(19) United States
(12) Patent Application Publication
(10) Pub. No.: US 2025/0120240 A1
(43) Pub. Date: Apr. 10, 2025

(54) CHIP STRUCTURE AND METHOD OF MANUFACTURING THE SAME, DISPLAY SUBSTRATE, AND DISPLAY APPARATUS

(71) Applicant: BOE TECHNOLOGY GROUP CO., LTD., Beijing (CN)

(72) Inventors: Wei LI, Beijing (CN); Mingxing WANG, Beijing (CN); Zhiqiang JIAO, Beijing (CN); Qian SUN, Beijing (CN); Huajie YAN, Beijing (CN); Yichi ZHANG, Beijing (CN)

(73) Assignee: BOE TECHNOLOGY GROUP CO., LTD., Beijing (CN)

(21) Appl. No.: 18/729,170

(22) PCT Filed: Jan. 3, 2023
(86) PCT No.: PCT/CN2023/070140

§ 371 Date: Jul. 16, 2024

(51) Int. Cl. H10H 29/85; H10H 20/01; H10H 20/812; H10H 20/825; H10H 29/01; H10H 29/852; H10H 29/855

(52) U.S. Cl. CPC H10H 29/857; H10H 20/01335; H10H 20/812; H10H 20/825; H10H 29/0361; H10H 29/0364; H10H 29/8517; H10H 29/852; H10H 29/8552

(57) ABSTRACT

A chip structure includes a chip wafer unit and a color conversion substrate unit disposed on a light-exit side of the chip wafer unit. The chip wafer unit includes a light-emitting layer and an electrode layer sequentially stacked in a first direction. The light-emitting layer includes light-emitting portions. Each light-emitting portion includes at least two light-emitting sub-portions. The electrode layer includes a cathode, connection electrodes, and anodes in one-to-one correspondence with the light-emitting portions. The at least two light-emitting sub-portions are sequentially connected through at least one connection electrode. Among the at least two light-emitting sub-portions sequentially connected, a first one light-emitting sub-portion is a first selected light-emitting sub-portion, and a last one light-emitting sub-portion is a second selected light-emitting sub-portion. The first selected light-emitting sub-portion is connected to the cathode, and the second selected light-emitting sub-portion is connected to an anode.

### CROSS-REFERENCE TO RELATED APPLICATION

This application is a national phase entry under 35 USC 371 of International Patent Application No. PCT/CN2023/070140, filed on Jan. 3, 2023, which is incorporated herein by reference in its entirety.

### TECHNICAL FIELD

The present disclosure relates to the field of display technologies, and in particular, to a chip structure, a method of manufacturing a chip structure, a display substrate, and a display apparatus.

### BACKGROUND

Micro light-emitting diode (Micro-LED) display devices are a new generation of display technology due to their advantages such as high brightness, high luminous efficiency, low power consumption, and fast response speed.

### SUMMARY

In an aspect, a chip structure is provided. The chip structure includes: a chip wafer unit and a color conversion substrate unit disposed on a light-exit side of the chip wafer unit. The chip wafer unit includes a light-emitting layer and an electrode layer sequentially stacked in a first direction. The electrode layer includes a cathode, a plurality of connection electrodes, and a plurality of anodes in one-to-one correspondence with a plurality of light-emitting portions. The light-emitting layer includes the plurality of light-emitting portions, and each light-emitting portion includes at least two light-emitting sub-portions. The first direction is a direction perpendicular to a lower surface of the color conversion substrate unit and pointing from the color conversion substrate unit to the chip wafer unit.

At least two light-emitting sub-portions included in each light-emitting portion are sequentially connected through at least one connection electrode; among the at least two light-emitting sub-portions sequentially connected, a first one light-emitting sub-portion is a first selected light-emitting sub-portion, and a last one light-emitting sub-portion is a second selected light-emitting sub-portion; the first selected light-emitting sub-portion is connected to the cathode, and the second selected light-emitting sub-portion is connected to an anode corresponding to the light-emitting portion.

In some embodiments, a quantity of light-emitting sub-portions included in each light-emitting portion of the plurality of light-emitting portions is the same.

In some embodiments, light-emitting sub-portions include first light-emitting sub-portions, second light-emitting sub-portions, and third light-emitting sub-portions.

The plurality of light-emitting portions include a first light-emitting portion, a second light-emitting portion and a third light-emitting portion. The first light-emitting portion includes at least two first light-emitting sub-portions. The second light-emitting portion includes at least two second light-emitting sub-portions. The third light-emitting portion includes at least two third light-emitting sub-portions.

In some embodiments, a surface of the color conversion substrate unit facing the chip wafer unit is a first surface. The chip wafer unit further includes N-type gallium nitride portions. The N-type gallium nitride portions include first N-type gallium nitride patterns and a plurality of second N-type gallium nitride patterns, and the first N-type gallium nitride patterns are connected to the cathode. Each light-emitting sub-portion includes an N-type gallium nitride portion and a light-emitting functional portion that are stacked in the first direction. A boundary of an orthographic projection of the N-type gallium nitride portion on the first surface surrounds a boundary of an orthographic projection of the light-emitting functional portion on the first surface.

An N-type gallium nitride portion included in the first selected light-emitting sub-portion is a first N-type gallium nitride pattern, and an N-type gallium nitride portion included in a light-emitting sub-portion other than the first selected light-emitting sub-portion is a second N-type gallium nitride pattern.

In some embodiments, the light-emitting functional portion includes a quantum well portion, a P-type gallium nitride portion and a conductive portion that are stacked in the first direction; each anode of the plurality of anodes is arranged corresponding to a single second selected light-emitting sub-portion, and is connected to a conductive portion of the single second selected light-emitting sub-portion.

The chip wafer unit further includes: a transfer layer and a first passivation layer. The transfer layer includes a cathode transfer electrode disposed on a side of the first N-type gallium nitride pattern away from the first surface. An orthographic projection of the cathode transfer electrode on the first surface does not overlap with the orthographic projection of the light-emitting functional portion on the first surface. The first passivation layer is disposed on a side of the light-emitting layer away from the first surface and covers the light-emitting layer and the transfer layer. The electrode layer is disposed on a side of the first passivation layer away from the light-emitting layer. The first passivation layer includes: a first via hole, a plurality of second via holes and a plurality of third via holes.

The first via hole reaches the cathode transfer electrode. Each second via hole is arranged corresponding to a single light-emitting sub-portion, and the plurality of second via holes reach conductive portions of light-emitting sub-portions, respectively; the plurality of second via holes include a plurality of transfer via holes and a plurality of connection via holes, and each transfer via hole of the plurality of transfer via holes is arranged corresponding to one second selected light-emitting sub-portion. Each third via hole is arranged corresponding to a single light-emitting sub-portion other than the first selected light-emitting sub-portion, and the plurality of third via holes reach N-type gallium nitride portions of the light-emitting sub-portions, respectively.

The cathode is connected to the cathode transfer electrode through the first via hole; each anode is connected to the conductive portion of the single second selected light-emitting sub-portion through a transfer via hole; a first end of any one connection electrode of the plurality of connection electrodes is connected to a conductive portion of one light-emitting sub-portion of the at least two light-emitting sub-portions through a connection via hole, and a second end of the connection electrode is connected to an N-type gallium nitride portion of another light-emitting sub-portion through a third via hole.

In some embodiments, the chip wafer unit further includes a second passivation layer and a pad layer that are stacked in the first direction.

The second passivation layer covers the electrode layer. The second passivation layer includes: a fourth via hole arranged corresponding to the first via hole and a plurality of fifth via holes arranged corresponding to the plurality of transfer via holes. The fourth via hole reaches the cathode, and the plurality of fifth via holes respectively reach the anodes.

The pad layer includes: a first pad and a plurality of second pads in one-to-one correspondence with the plurality of anodes. The first pad is connected to the cathode through the fourth via hole, and each second pad is connected to an anode through a fifth via hole.

In some embodiments, the chip wafer unit further includes: a buffer layer and a U-type gallium nitride layer that are stacked in the first direction. The U-type gallium nitride layer is disposed between the buffer layer and the light-emitting layer. The first passivation layer further covers the U-type gallium nitride layer and the buffer layer.

In some embodiments, a thickness of the buffer layer in the first direction is in a range of 4.5 μm to 5.5 μm.

In some embodiments, a boundary of an orthographic projection of the quantum well portion of the light-emitting sub-portion on the first surface has a size in a second direction that is in a range of 18 μm to 21 μm and a size in a third direction that is in a range of 18 μm to 21 μm. The second direction intersects the third direction, the second direction is perpendicular to the first direction, and the third direction is perpendicular to the first direction.

In some embodiments, in any one light-emitting sub-portion, a distance between a boundary of an N-type gallium nitride portion and a boundary of a P-type gallium nitride portion is r1. In the second selected light-emitting sub-portion, a distance between a boundary of a second N-type gallium nitride pattern and a boundary of a corresponding third via hole is r2, where r1>r2.

In some embodiments, in the light-emitting sub-portion, the distance between the boundary of the N-type gallium nitride portion and the boundary of the P-type gallium nitride portion is in a range of 9.5 μm to 10.5 μm. A distance between a boundary of any second N-type gallium nitride pattern and any third via hole is greater than or equal to 5 μm.

A distance between the first N-type gallium nitride pattern and any one of the plurality of second N-type gallium nitride patterns is greater than or equal to 6 μm. A distance between any two of the plurality of second N-type gallium nitride patterns is greater than or equal to 6 μm.

In some embodiments, a distance between the cathode transfer electrode and the quantum well portion is greater than or equal to 8 μm.

In some embodiments, the color conversion substrate unit includes: a first substrate, a color filter layer, a definition dam layer, a color conversion layer, an encapsulation layer and a bonding layer. The color filter layer is disposed on a side of the first substrate facing the chip wafer unit. The color filter layer includes a black matrix and a plurality of filter portions defined by the black matrix, and the plurality of filter portions being in one-to-one correspondence with the plurality of light-emitting portions. The plurality of filter portions include: a first color filter portion arranged corresponding to the first light-emitting portion, a second color filter portion arranged corresponding to the second light-emitting portion, and a third color filter portion arranged corresponding to the third light-emitting portion.

The definition dam layer is disposed on a side of the color filter layer away from the first substrate, and includes a plurality of opening regions in one-to-one correspondence with the plurality of filter portions. The plurality of opening regions include: a first opening region arranged corresponding to the first color filter portion, a second opening region arranged corresponding to the second color filter portion, and a third opening region arranged corresponding to the third color filter portion. The color conversion layer is disposed in the plurality of opening regions and includes color conversion portions and a filling portion. The filling portion is disposed in the third opening region. The encapsulation layer covers the definition dam layer and the color conversion layer. The bonding layer is disposed on a side of the encapsulation layer away from the first substrate.

In some embodiments, the color conversion portions include a first color conversion portion disposed in the first opening region and a second color conversion portion disposed in the second opening region. The first color conversion portion includes a first quantum dot conversion portion or a first fluorescent color conversion portion; the second color conversion portion includes a second quantum dot conversion portion or a second fluorescent color conversion portion; and the filling portion includes a scattering particle portion or a transparent glue.

In some embodiments, a light-emitting region of the chip structure corresponding to the first light-emitting portion is a light-emitting region of a first color, a light-emitting region of the chip structure corresponding to the second light-emitting portion is a light-emitting region of a second color, and a light-emitting region of the chip structure corresponding to the third light-emitting portion is a light-emitting region of a third color. The first color is red, the second color is green, and the third color is blue.

In some embodiments, a light-emitting area of the first light-emitting portion is equal to a light-emitting area of the second light-emitting portion, and the light-emitting area of the first light-emitting portion is greater than or equal to a light-emitting area of the third light-emitting portion.

In another aspect, a display substrate is provided. The display substrate includes a plurality of chip structures according to any one of the above embodiments, and a second substrate. A second passivation layer is provided on a side of the electrode layer away from the color conversion substrate unit, and a pad layer is provided on a side of the second passivation layer away from the electrode layer.

A circuit structure is provided on a side of the second substrate facing the chip structures; the pad layer faces the second substrate and is connected to the circuit structure. A minimum value of a distance between the second passivation layer and the second substrate is in a range of 15 μm to 25 μm.

In yet another aspect, a display apparatus is provided, including the display substrate as described in any of the above embodiments.

In yet another aspect, a method of manufacturing a chip structure is provided, which includes the following steps.

A first initial wafer is formed. The first initial wafer includes a plurality of initial chip wafer units; each initial chip wafer unit includes a plurality of chip structure regions; each initial chip wafer unit further includes: an initial substrate, and an initial light-emitting layer and an initial electrode layer that are sequentially stacked on a first surface of the initial substrate in a first direction; the initial light-emitting layer includes light-emitting portions, and each light-emitting portion includes at least two light-emitting sub-portions; the initial electrode layer includes cathodes, connection electrodes, and anodes in one-to-one correspondence with the light-emitting portions.

A second initial wafer is formed. The second initial wafer includes a plurality of initial color conversion substrate units.

The second initial wafer is arranged on a light-exit side of the first initial wafer for assembly to obtain a chip wafer structure. The chip wafer structure includes a plurality of chip structures.

The chip wafer structure is cut along border lines of the chip structure regions to obtain the plurality of chip structures. Each chip structure includes a plurality of light-emitting portions, and each light-emitting portion includes at least two light-emitting sub-portions; each chip structure further includes a cathode, a plurality of connection electrodes, and a plurality of anodes in one-to-one correspondence with the plurality of light-emitting portions; the at least two light-emitting sub-portions included in each light-emitting portion are sequentially connected through at least one connection electrode; among the at least two light-emitting sub-portions sequentially connected, a first one light-emitting sub-portion is a first selected light-emitting sub-portion, and a last one light-emitting sub-portion is a second selected light-emitting sub-portion; the first selected light-emitting sub-portion is connected to the cathode, and the second selected light-emitting sub-portion is connected to an anode corresponding to the light-emitting portion.

In some embodiments, in a step of forming an initial chip unit, the initial light-

emitting layer includes an initial N-type gallium nitride layer and an initial light-emitting functional layer sequentially stacked in the first direction, and the at least two light-emitting sub-portions include the first selected light-emitting sub-portion and the second selected light-emitting sub-portion.

The initial N-type gallium nitride layer includes a plurality of N-type gallium nitride portions, and the plurality of N-type gallium nitride portions include a plurality of first N-type gallium nitride patterns and a plurality of second N-type gallium nitride patterns; each chip structure region includes first N-type gallium nitride patterns and second N-type gallium nitride patterns.

The initial light-emitting functional layer includes a quantum well layer, a P-type gallium nitride layer, and a conductive layer that are sequentially stacked in the first direction, wherein the quantum well layer includes a plurality of quantum well portions, the P-type gallium nitride layer includes a plurality of P-type gallium nitride portions, and the conductive layer includes a plurality of conductive portions; each light-emitting functional portion includes a quantum well portion, a P-type gallium nitride portion and a conductive portion that are stacked; an N-type gallium nitride portion included in the first selected light-emitting sub-portion is a first N-type gallium nitride pattern, and an N-type gallium nitride portion included in the second selected light-emitting sub-portion is a second N-type gallium nitride pattern.

Before a step of cutting the chip wafer structure, the method further includes the following steps.

An initial transfer layer is formed. The initial transfer layer includes a plurality of cathode transfer electrodes, and each cathode transfer electrode is disposed on a side of a first N-type gallium nitride pattern away from the initial substrate.

An initial first passivation layer is formed. The initial first passivation layer is disposed on a side of the initial light-emitting layer away from the initial substrate; the initial first passivation layer includes a plurality of first via holes, a plurality of second via holes, and a plurality of third via holes; each first via hole is arranged corresponding to a first selected light emitting sub-portion, and the plurality of first via holes respectively reach the cathode transfer electrodes; each second via hole is arranged corresponding to a light-emitting sub-portion, and the plurality of second via holes respectively reach the conductive portions; each third via hole is arranged corresponding to a light-emitting sub-portion other than the first selected light-emitting sub-portion, and the plurality of third via holes respectively reach N-type gallium nitride portions of light-emitting sub-portions.

An initial second passivation layer is formed. The initial second passivation layer is disposed on a side of the initial electrode layer away from the initial substrate; the initial second passivation layer includes a plurality of fourth via holes in one-to-one correspondence with the plurality of first via holes, and a plurality of fifth via holes in one-to-one correspondence with a plurality of transfer via holes included in the plurality of second via holes.

A pad layer is formed. The pad layer includes a plurality of first pads and a plurality of second pads, each first pad is connected to a cathode through a fourth via hole, and each second pad is connected to one of the plurality of anodes through a fifth via hole.

### BRIEF DESCRIPTION OF THE DRAWINGS

In order to describe technical solutions in the present disclosure more clearly. the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a sectional view showing a structure of a chip structure, in accordance with some embodiments;

FIG. 2A is a plan view showing a structure of a light-emitting portions of a chip structure, in accordance with some embodiments;

FIG. 2B is a plan view showing a structure of light-emitting portions of a chip structure, in accordance with some other embodiments;

FIG. 2C is a plan view showing a structure of light-emitting portions of a chip structure, in accordance with yet some other embodiments;

FIG. 3A is a sectional view showing a structure of a chip wafer unit of a chip structure, in accordance with some embodiments;

FIG. 3B is a sectional view showing a structure of a chip wafer unit of a chip structure, in accordance with some other embodiments;

FIG. 4A is a structural diagram of a chip wafer unit of a chip structure, in accordance with some embodiments;

FIG. 4B is a structural diagram of a chip wafer unit of a chip structure, in accordance with some other embodiments;

FIG. 4C is a structural diagram of a chip wafer unit of a chip structure, in accordance with yet some other embodiments;

FIG. 5 is a sectional view showing a structure of a color conversion substrate unit of a chip structure, in accordance with some embodiments;

FIG. 6 is a flow diagram of a method of manufacturing a chip structure, in accordance with some embodiments;

FIG. 7A is a diagram showing a structure of a first initial wafer corresponding to step S1 according to the method in FIG. 6;

FIG. 7B is a diagram showing a structure of an initial chip wafer unit corresponding to step S1 according to the method in FIG. 6;

FIG. 8A is a diagram showing a structure of a second initial wafer corresponding to step S2 according to the method in FIG. 6;

FIG. 8B is a diagram showing a structure of an initial color conversion substrate unit corresponding to step S2 according to the method in FIG. 6;

FIG. 9 is a diagram showing a structure corresponding to step S4 according to the method in FIG. 6;

FIG. 10 is a flow diagram of step S1 according to the method in FIG. 6;

FIG. 11 is a diagram showing a structure corresponding to step S11 according to the method in FIG. 10;

FIG. 12 is a diagram showing a structure corresponding to step S12 according to the method in FIG. 10;

FIG. 13 is a diagram showing a structure corresponding to steps S13 and S14 according to the method in FIG. 10;

FIG. 14 is a diagram showing a structure corresponding to step S15 according to the method in FIG. 10;

FIG. 15 is a diagram showing a structure corresponding to step S16 according to the method in FIG. 10;

FIG. 16 is a diagram showing a structure corresponding to step S17 according to the method in FIG. 10;

FIG. 17 is a diagram showing a structure corresponding to step S18 according to the method in FIG. 10;

FIG. 18 is a flow diagram of step S2 according to the method in FIG. 6;

FIG. 19 is a diagram showing a structure corresponding to step S21 according to the method in FIG. 18;

FIG. 20 is a diagram showing a structure corresponding to steps S22 and S23 according to the method in FIG. 18;

FIG. 21 is a diagram showing a structure corresponding to steps S24 and S25 according to the method in FIG. 18;

FIG. 22 is a diagram showing a structure corresponding to step S3 of the method in FIG. 6;

FIG. 23 is a sectional view showing a structure of a display substrate, in accordance with some embodiments;

FIG. 24 is a plan view showing a structure of a display substrate, in accordance with some embodiments; and

FIG. 25 is a structural diagram of a display apparatus, in accordance with some embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the term “multiple”, “a plurality of” or “the plurality of” means two or more unless otherwise specified.

In the description of some embodiments, the expressions “coupled” and “connected” and derivatives thereof may be used. The term “connected” should be understood in a broad sense. For example, the term “connected” may represent a fixed connection, a detachable connection, or a one-piece connection; alternatively, the term “connected” may represent a direct connection, or an indirect connection through an intermediate medium. The term “coupled”, for example, indicates that two or more components are in direct physical or electrical contact. However, the term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

At present, red micro light-emitting diodes (Micro-LEDs) are mostly made of aluminum gallium indium phosphorus (AlGaInP), and the efficiency thereof reaches over 60% under normal chip size. However, when the chip size reduces to the micron level, the efficiency will drop to less than 1%. Moreover, in the display process, the light-emitting power consumption of the LED chip only accounts for 30% of its overall power consumption, and the current cannot be fully used, causing the problem of energy waste. In addition, the disadvantage of AlGaInP in the mass transfer process is obvious. Mass transfer requires the material with good mechanical strength to avoid cracking during the chip picking and placing process. Thus, the poor mechanical properties of AlGaInP will make the mass transfer more difficult.

In light of this, some embodiments of the present disclosure provide a chip structure 10, a method of manufacturing the chip structure, a display substrate 100, and a display apparatus 1000, so as to solve the above technical problems. The chip structure 10, the method of manufacturing the chip structure, the display substrate 100, and the display apparatus 1000 provided in the embodiments of the present disclosure will be introduced below.

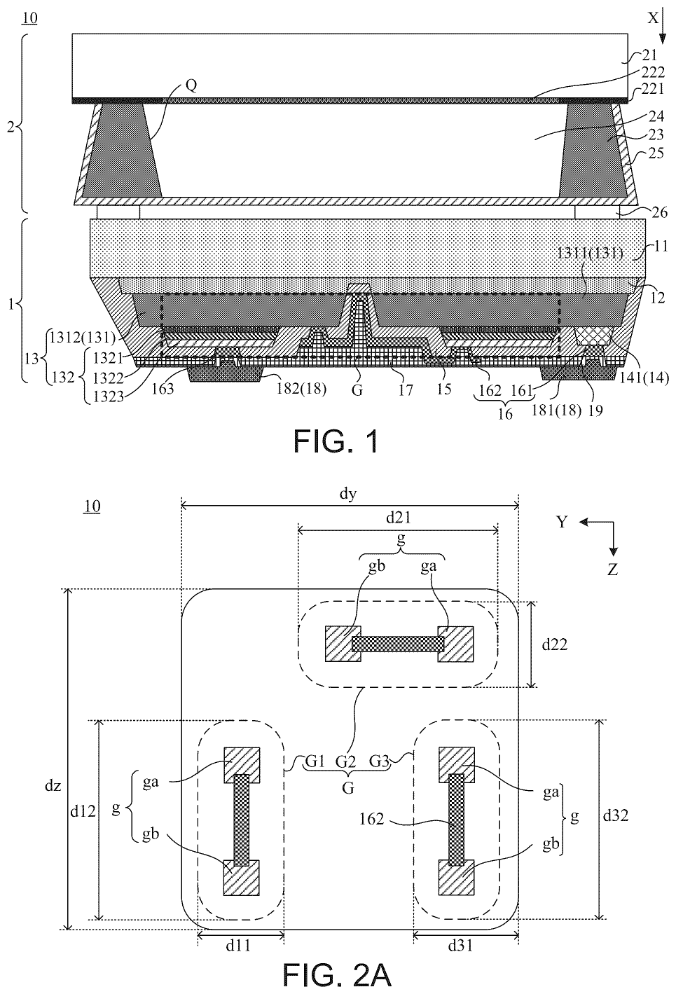

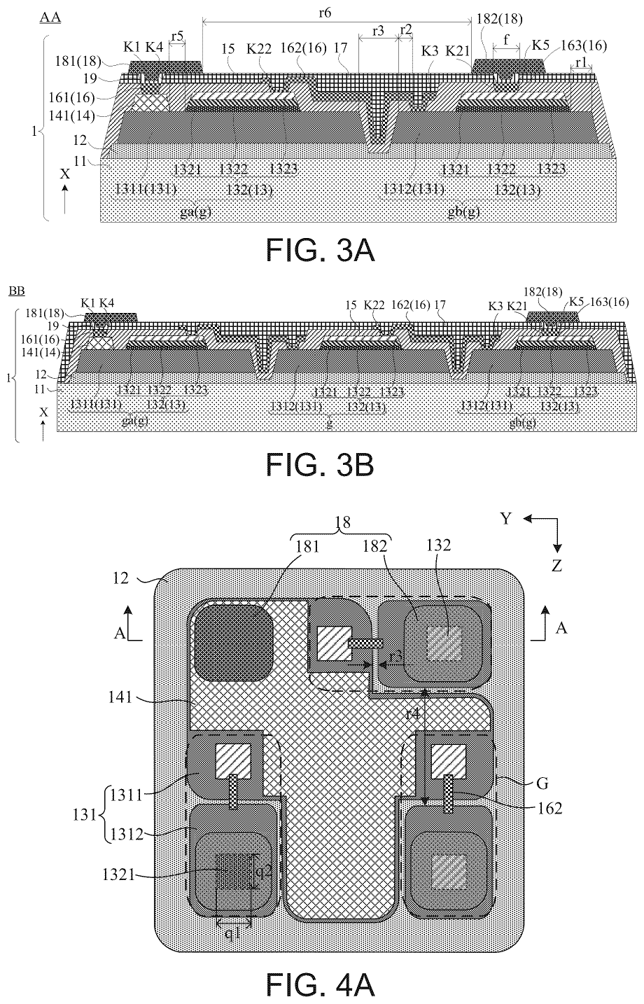

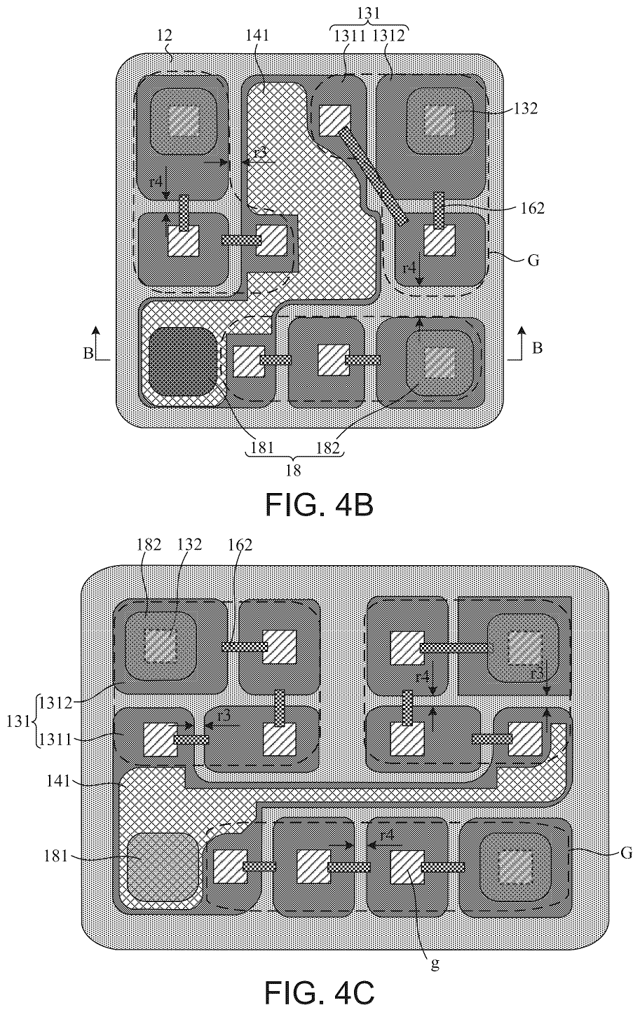

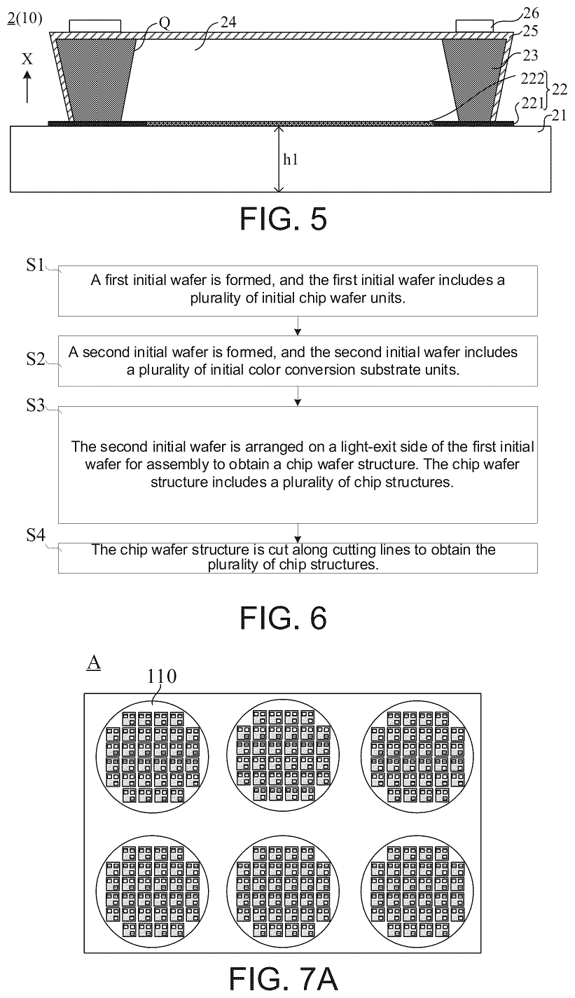

FIG. 1 is a sectional view showing a structure of a chip structure, in accordance with some embodiments. FIG. 3A is a sectional structural view taken along the section line AA in FIG. 4A. FIG. 3B is a sectional structural view taken along the section line BB in FIG. 4B. FIG. 5 is a sectional view showing a structure of a color conversion substrate unit of a chip structure, in accordance with some embodiments.

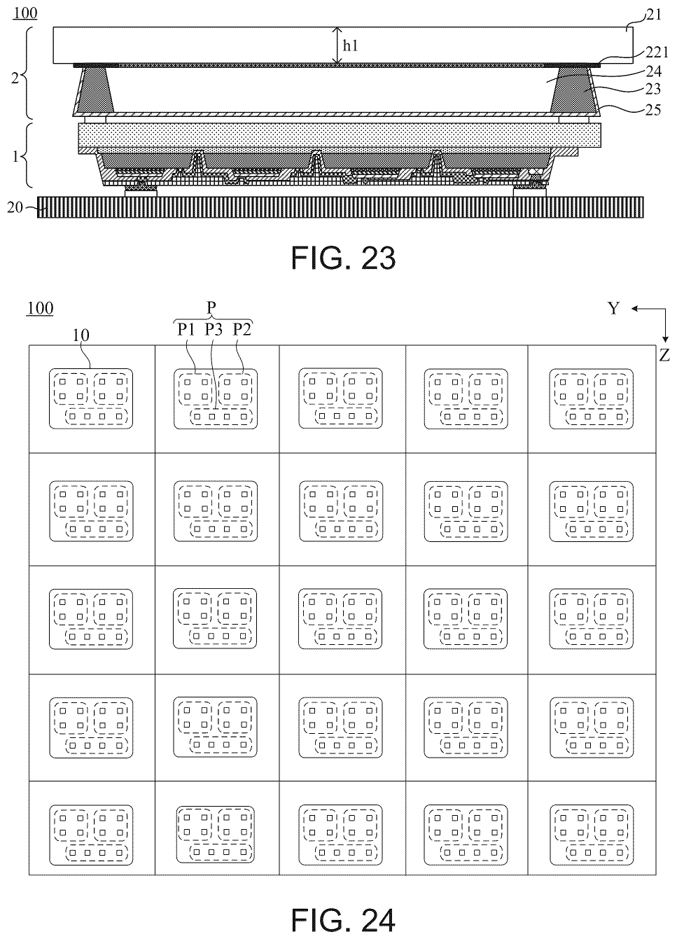

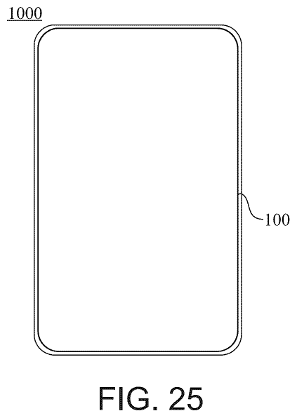

FIGS. 6 to 22 are flow diagrams of a method of manufacturing a chip structure and structural diagrams corresponding to steps, in accordance with some embodiments. FIG. 23 is a sectional view showing a structure of a display substrate, in accordance with some embodiments. FIG. 24 is a plan view showing a structure of a display substrate, in accordance with some embodiments. FIG. 25 is a structural diagram of a display apparatus, in accordance with some embodiments.

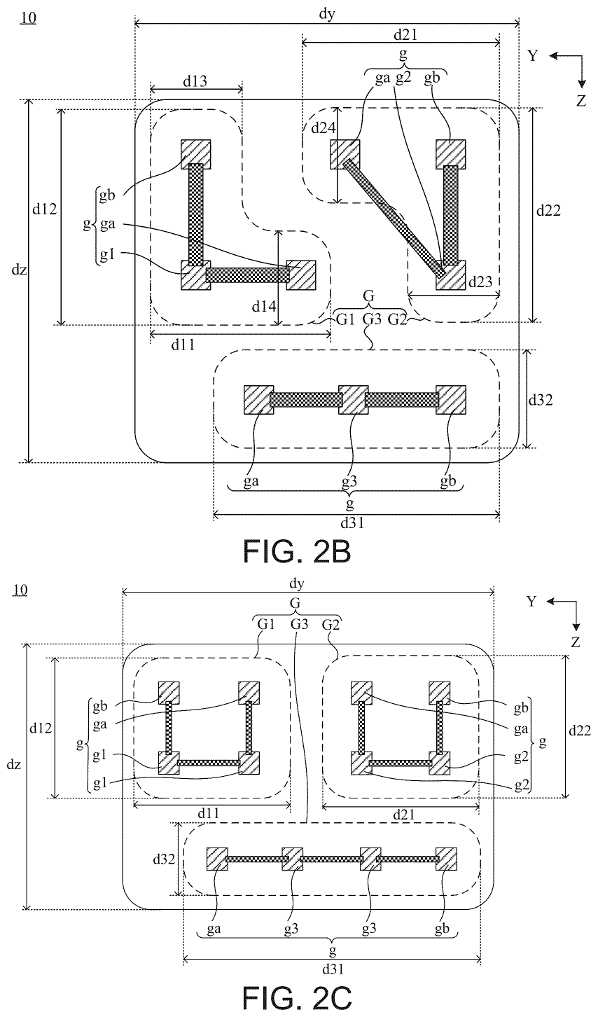

In order to clearly describe the positional relationship and connection relationship of each light-emitting sub-portion in a light-emitting portion, a color conversion substrate unit and other structures of the chip structure in FIG. 1 are removed, resulting in FIGS. 2A, 2B and 2C showing a structure that only includes light-emitting sub-portions and connection electrodes.

In order to clearly describe the positional relationship and connection relationship of each part in a light-emitting portion, a color conversion substrate unit and other structures (such as a first passivation layer and a second passivation layer) of a chip wafer unit in the chip structure in FIG. 1 are removed, resulting in FIGS. 4A, 4B and 4C showing a structure that only includes a light-emitting layer, a transfer layer, a pad layer, etc. In order to clearly describe a size of a quantum well portion in a light-emitting functional portion, regarding to a light-emitting sub-portion at the lower left corner in FIG. 4A, a conductive portion and a P-type gallium nitride portion at the top are removed to illustrate a quantum well portion at the bottom.

In some embodiments, as shown in FIG. 1, the chip structure 10 includes: a chip wafer unit 1 and a color conversion substrate unit 2 disposed on a light-exit side of the chip wafer unit 1. The chip wafer unit 1 includes a light-emitting layer 13 and an electrode layer 16 sequentially stacked in a first direction X. The electrode layer 16 includes: a cathode 161, a plurality of connection electrodes 162, and a plurality of anodes 163 in one-to-one correspondence with a plurality of light-emitting portions G.

As shown in FIGS. 1, 2A, 2B and 2C, the light-emitting layer 13 includes the plurality of light-emitting portions G, and each light-emitting portion G includes at least two light-emitting sub-portions g. The first direction X is a direction pointing from the color conversion substrate unit 2 to the chip wafer unit 1.

As shown in FIGS. 2A, 2B, 2C, 3A and 3B, among the plurality of light-emitting portions G included in the chip wafer unit 1, at least two light-emitting sub-portions g included in each light-emitting portion G are sequentially connected through at least one connection electrode 162. Among the at least two light-emitting sub-portions g sequentially connected, the first one light-emitting sub-portion g is a first selected light-emitting sub-portion ga, and the last one light-emitting sub-portion g is a second selected light-emitting sub-portion gb. The first selected light-emitting sub-portion ga is connected to the cathode 161, and the second selected light-emitting sub-portion gb is connected to an anode 163 corresponding to the light-emitting portion G to which the second selected light-emitting sub-portion gb belongs.

It can be understood that, as shown in FIGS. 2A, 2B and 2C, first selected light-emitting sub-portions ga and second selected light-emitting sub-portions gb included in the chip wafer unit 1 are the same in quantity.

For example, as shown in FIGS. 3A and 3B, a material of the electrode layer 16 includes but is not limited to at least one of gold, silver, copper, titanium, aluminum, molybdenum, nickel gold, or conductive silver glue.

In some examples, as shown in FIG. 2A, each light-emitting portion G includes two light-emitting sub-portions g. The two light-emitting sub-portions g included in each light-emitting portion G are respectively a first selected light-emitting sub-portion ga and a second selected light-emitting sub-portion gb. The first selected light-emitting sub-portion ga and the second selected light-emitting sub-portion gb are connected through one connection electrode 162.

In this case, a dimension dy of the chip structure 10 in a second direction Y is, for example, 215 μm; and a dimension dz of the chip structure in a third direction Z is, for example, 225 μm. A plane defined by the second direction Y and the third direction Z is perpendicular to the first direction X.

In some other examples, as shown in FIG. 2B, each light-emitting portion G includes three light-emitting sub-portions g. The three light-emitting sub-portions g included in each light-emitting portion G include a first selected light-emitting sub-portion ga, a light-emitting sub-portion g, and a second selected light-emitting sub-portion gb that are sequentially connected. The three light-emitting sub-portions g are sequentially connected through two connection electrodes 162.

In this case, the dimension dy of the chip structure 10 in the second direction Y is, for example, 269 μm, and the dimension dz of the chip structure in the third direction Z is, for example, 260 μm.

In yet some other examples, as shown in FIG. 2C, each light-emitting portion G includes four light-emitting sub-portions g. The four light-emitting sub-portions g included in each light-emitting portion G include a first selected light-emitting sub-portions ga, a light-emitting sub-portion g, a light-emitting sub-portion g, and a second selected light-emitting sub-portion gb that are sequentially connected. The four light-emitting sub-portions g are sequentially connected through three connection electrodes 162.

In this case, the dimension dy of the chip structure in the second direction Y is, for example, 329 μm, and the dimension dz of the chip structure in the third direction Z is, for example, 239 μm.

For example, when the chip structure is working, the power consumption of the chip structure is P=I×V. Here, I is a value of the working current of the chip structure; V is a value of the working voltage of the chip structure, and V is a sum of values of working voltages of all component structures included in the chip structure; and I and V are both fixed values. It can be understood that, in this case, the value of P is also a fixed value.

The chip structure adopts a constant current working mode. Since the resistance value of each light-emitting sub-portion is constant, it can be understood that, in the series structure formed by the at least two light-emitting sub-portions included in each light-emitting section, the working voltage of each light-emitting sub-portion may be accumulated, so that a total working voltage of the light-emitting portion is an accumulation value of working voltages of a plurality of light-emitting sub-portions, resulting in a high-voltage chip structure. In this way, in the chip structure, the working voltage of each light-emitting portion is V₁=n×V_{LED}, and the working voltage of the plurality of light-emitting portions of the chip structure is V₂=m×n×V_{LED}, where V_{LED} is the working voltage of each light-emitting sub-portion, m is the number of light-emitting portions included in the chip structure, n is the number of light-emitting sub-portions included in each light-emitting portion, m and n are positive integers, and n is greater than or equal to 2 (n≥2).

In this way, the working voltage V₂ of the plurality of light-emitting portions of the chip structure increases, and the power consumption P of the plurality of light-emitting portions also increases. Therefore, in the chip structure, the proportion of the power consumption of the plurality of light-emitting portions in the power consumption of the entire chip structure is increased, which improves the current utilization rate of the chip structure and is conducive to reducing the power consumption of other structures in the chip structure except for the light-emitting portions and reducing energy waste. As a result, it avoids the problem that during the display, the light-emitting power consumption of the chip structure accounts for a low proportion of the overall power consumption and the current cannot be fully utilized, causing energy waste.

In some embodiments, as shown in FIGS. 2A, 2B and 2C, in the chip structure 10, the number of light-emitting sub-portions g included in each light-emitting portion G of the plurality of light-emitting portions G is the same.

For example, as shown in FIGS. 2A, 2B and 2C, the number of light-emitting sub-portions g included in each light-emitting portion is 2, 3, 4, 5, etc.

This is only used here as an illustration of a possible implementation. The number of light-emitting sub-portions included in each light-emitting portion is not limited, which can be set according to needs.

At least two light-emitting sub-portions g included in each light-emitting portion G are sequentially connected through connection electrode(s) 162, so that the at least two light-emitting sub-portions g included in each light-emitting portion G form a series structure. In this way, each light-emitting portion G includes the same number of light-emitting sub-portions g that form a series structure, thereby ensuring that when the chip structure 10 is working, the working current of each light-emitting portion G is maintained at a similar level. Therefore, the light-emitting brightness of each light-emitting portion G in the chip structure 10 is the same or substantially the same, which ensures the uniformity of the light-emitting brightness of the chip structure 10.

In some embodiments, as shown in FIGS. 2A, 2B and 2C, a light-emitting area of a first light-emitting portion G1 is equal to a light-emitting area of a second light-emitting portion G2, and the light-emitting area of the first light-emitting portion G1 is greater than or equal to a light-emitting area of a third light-emitting portion G3.

In some embodiments, in the chip structure 10, a light-emitting region corresponding to the first light-emitting portion G1 is a light-emitting region of a first color, a light-emitting region corresponding to the second light-emitting portion G2 is a light-emitting region of a second color, and a light-emitting region corresponding to the third light-emitting portion G3 is a light-emitting region of a third color.

For example, the first color is red, the second color is green, and the third color is blue.

For example, each light-emitting portion G of the plurality of light-emitting portions G of the chip wafer unit 1 is configured to emit light of one of a plurality of colors.

In some examples, the plurality of light-emitting portions G emit light of the same color.

For example, light of the plurality of colors includes, but is not limited to, blue light.

In some examples, as shown in FIG. 1, the plurality of light-emitting portions G are each configured to emit blue light. The color conversion substrate unit 2 is disposed on the light-exit side of the chip wafer unit 1. The color conversion substrate unit 2 is provided therein with a color conversion layer 24 corresponding to a light-exit side of each light-emitting portion G. For example, after passing through the color conversion layer, blue light emitted from each light-emitting portion can maintain blue light to exit or be converted into red light or green light to exit. In the chip structure 10 provided in the embodiments of the present disclosure, the color conversion substrate unit 2 performs color conversion on the light emitted by the chip wafer unit 1. In this way, the plurality of light-emitting portions G of the chip wafer unit 1 can emit light of the same color; for example, the plurality of light-emitting portions G are configured to emit blue light; and the chip structure 10 can still achieve the emission of light of a plurality of colors.

For example, among the plurality of light-emitting portions G included in the chip wafer unit 1, blue light emitted from a light-emitting portion G maintains blue light to exit after passing through a color conversion layer 24, and blue light emitted from another light-emitting portion G is converted into red light to exit after passing through a color conversion layer 24, and blue light emitted from still another light-emitting portion G is converted into green light to exit after passing through a color conversion layer 24.

In a case where the chip structure 10 is used in display, for example, only the chip wafer unit 1 of blue light needs to be produced. Through the color conversion substrate unit 2, the blue light emitted by the chip wafer unit 1 of blue light is kept as blue light for emission, or is converted into light of another color (e.g., red light or green light) for emission.

It can be understood that, in this way, when the chip structure 10 is used in display, although there is no need to use AlGaInP to fabricate chips of red light, the red light display can also be realized. As a result, it avoids the problem of cracks in the chips of red light which are made of AlGaInP during the picking and placing in the mass transfer process.

Moreover, the blue light emitted by the light-emitting portion G and the color conversion layer 24 of the color conversion substrate unit 2 are combined to realize the red light emission, thereby solving the problem of low luminous efficiency of the chip of red light when the chip size is reduced to the micron level.

For example, the chip wafer unit 1 and the color conversion substrate unit 2 are separately fabricated, and then the chip wafer unit 1 and the color conversion substrate unit 2 are bonded together, for example, through a bonding layer, to form the chip structure 10. Thereby, the transfer efficiency of Micro-LEDs may be improved, the chip thickness is reduced, and the preparation accuracy and product yield is improved. The bonding effect of the bonding layer 26 may be adhesive bonding effect or metallic bonding effect. This is only used as an illustration of a possible implementation, and is not intended to limit the technical solutions of the present disclosure.

For example, the bonding layer 26 is an adhesive bonding layer. Compared with a metallic bonding layer, the adhesive bonding layer has high shear strength and good bonding stability, which effectively avoids the cracks at the bonding position of the chip wafer unit 1 and the color conversion substrate unit 2.

In some embodiments, as shown in FIGS. 2A, 2B and 2C, the plurality of light-emitting portions G include: a first light-emitting portion G1, a second light-emitting portion G2, and a third light-emitting portion G3. The light-emitting sub-portions g include: first light-emitting sub-portions g1, second light-emitting sub-portions g2 and third light-emitting sub-portions g3. The first light-emitting portion G1 includes at least two first light-emitting sub-portions g1. The second light-emitting portion G2 includes at least two second light-emitting sub-portions g2. The third light-emitting portion G3 includes at least two third light-emitting sub-portions g3.

In some embodiments, as shown in FIGS. 1, 3A, 3B, 4A, 4B and 4C, the light-emitting layer 13 of the chip wafer unit 1 further includes N-type gallium nitride portions 131. The N-type gallium nitride portions 131 include first N-type gallium nitride patterns 1311 and a plurality of second N-type gallium nitride patterns 1312. The first N-type gallium nitride patterns 1311 are connected to the cathode 161.

It should be noted that the first N-type gallium nitride patterns 1311 and the plurality of second N-type gallium nitride patterns 1312 are located in the same layer and are separated from each other.

Referring to FIGS. 3A and 3B, the connection electrode 162 connects two light-emitting sub-portions g, and also partially fills a gap between the two light-emitting sub-portions g, so that side walls of the gap between the two light-emitting sub-portions g are covered, which can effectively reduce the sidewall effect and avoid light leakage and color interference of light emitted from the light-emitting sub-portions g. As a result, the light extraction effect of the chip structure 10 is improved.

It should be noted that when the chip structure is applied to the display apparatus, the display apparatus includes a plurality of pixels. For example, each pixel corresponds to one light-emitting sub-portion g. Light emitted by the light-emitting sub-portion g enters a corresponding pixel to cause the pixel to emit light. The sidewall effect means that light emitted by each light-emitting sub-portion g in the light-emitting portion G is scattering light of a large angle (i.e., exit angle of light), part of the light emitted by the light-emitting sub-portion g will enter the pixel corresponding to the light-emitting sub-portion g, and another part of the light emitted by the light-emitting sub-portion g cannot enter the pixel and may be transmitted to a range corresponding to an adjacent light-emitting sub-portion g, causing the light emission of a pixel corresponding to the adjacent light-emitting sub-portion g.

In some examples, each light-emitting portion G of the plurality of light-emitting portions G emits light of the same color. For example, at least two light-emitting sub-portions g included in each light-emitting portion G all emit light of the same color. In this way, adjacent light-emitting sub-portions g that are connected in series emit light of the same color, and sub-pixels corresponding to the light-emitting sub-portions g also emit light of the same color.

It should be noted that even if the light-emitting sub-portions g connected in series emit light of the same color, when light emitted by one of the light-emitting sub-portions g is directed to a color conversion layer 24 corresponding to an adjacent light-emitting sub-portion g, different light will appear, causing color interference.

A surface of the color conversion substrate unit 2 facing the chip wafer unit 1 is a first surface. The light-emitting sub-portion g includes an N-type gallium nitride portion 131 and a light-emitting functional portion 132 that are stacked in the first direction X. A boundary of an orthographic projection of the N-type gallium nitride portion 131 on the first surface surrounds a boundary of an orthographic projection of the light-emitting functional portion 132 on the first surface.

For example, the N-type gallium nitride portion 131 included in the first selected light-emitting sub-portion ga is a first N-type gallium nitride pattern 1311; and the N-type gallium nitride portion 131 included in a light-emitting sub-portion g other than the first selected light-emitting sub-portion ga is a second N-type gallium nitride pattern 1312.

As shown in FIGS. 4A, 4B and 4C, it can be seen that among the plurality of light-emitting portions G, the N-type gallium nitride portion 131 included in the first selected light-emitting sub-portion ga of each light-emitting portion G is the first N-type gallium nitride pattern 1311. That is, the first N-type gallium nitride patterns 1311 constitute an integrated structure with a large projection area, and the first N-type gallium nitride patterns 1311 are common structures. The first selected light-emitting sub-portions of the plurality of light-emitting portions are connected to the cathode through the first N-type gallium nitride patterns 1311. The plurality of second N-type gallium nitride patterns 1312 are independent structures, which are in one-to-one correspondence with light-emitting sub-portions g other than the first selected light-emitting sub-portions ga.

In some embodiments, as shown in FIGS. 3A, 3B, 4A, 4B and 4C, the light-emitting functional portion 132 includes a quantum well portion 1321, a P-type gallium nitride portion 1322 and a conductive portion 1323 that are stacked in the first direction X. Each anode 163 of the plurality of anodes 163 is arranged corresponding to a second selected light-emitting sub-portion gb, and is connected to the conductive portion 1323 of the second selected light-emitting sub-portion gb.

For example, as shown in FIGS. 3A and 3B, the quantum well portion 1321 is made of a self electro-optic effect material (a multi-quantum well (MQW) material with self electro-optic effect).

For example, as shown in FIGS. 3A and 3B, a material of the conductive portion 1323 includes, but is not limited to, indium tin oxide (ITO).

For example, orthographic projections of the quantum well portion 1321, the P-type gallium nitride portion 1322, and the conductive portion 1323 on the first surface overlap or substantially overlap.

In some embodiments, as shown in FIG. 4A, a dimension q1, in the second direction Y, of a boundary of the orthographic projection of the quantum well portion 1321 in the light-emitting sub-portion g on the first surface is in a range of 18 82 m to 21 μm, and a dimension q2, in the third direction Z, of the boundary of the orthographic projection of the quantum well portion 1321 in the light-emitting sub-portion g on the first surface is in a range of 18 μm to 21 μm. The second direction Y and the third direction Z intersect, the second direction Y is perpendicular to the first direction X, and the third direction Z is perpendicular to the first direction X.

Based on the chip structure 10 mentioned above, the light-emitting sub-portions g are sequentially connected through the connection electrodes 162 to form the light-emitting portion G of a series structure, which improves the light-emitting effect of the chip structure 10 while ensuring that the chip structure 10 can still maintain a small size. When the chip structure 10 is used in display, the pixel pitch of 0.4 mm can be achieved, thereby improving the display effect.

As shown in FIGS. 3A, 3B, 4A, 4B and 4C, the chip wafer unit 1 further includes: a transfer layer 14 and a first passivation layer 15. The transfer layer 14 is disposed on a side of the first N-type gallium nitride pattern(s) 1311 away from the first surface, and includes cathode transfer electrodes 141. An orthographic projection of the cathode transfer electrode 141 on the first surface does not overlap with the orthographic projection of the light-emitting functional portion 132 on the first surface. The first passivation layer 15 is disposed on a side of the light-emitting layer 13 away from the first surface. The first passivation layer 15 covers the light-emitting layer 13 and the transfer layer 14. The electrode layer 16 is disposed on a side of the first passivation layer 15 away from the light-emitting layer 13.

As shown in FIGS. 3A and 3B, the first passivation layer 15 includes: first via holes K1, a plurality of second via holes K2 (such as transfer via holes K21 and connection via holes K22), and a plurality of third via holes K3. The first via holes K1 reach the cathode transfer electrodes 141, respectively. Each second via hole K2 is arranged corresponding to a light-emitting sub-portion g, and the plurality of second via holes K2 respectively reach the conductive portions 1323 of the light-emitting sub-portions g. The plurality of second via holes K2 include a plurality of transfer via holes K21 and a plurality of connection via holes K22. Each transfer via hole K21 of the plurality of transfer via holes K21 is arranged corresponding to a second selected light-emitting sub-portion gb. The plurality of connection via holes K22 are arranged corresponding to all light-emitting sub-portions g other than the first selected light-emitting sub-portion ga, respectively. The connection via hole K22 reaches an N-type gallium nitride portion 131 of a light-emitting sub-portion g. Each third via hole K3 is arranged corresponding to a light-emitting sub-portion g other than the first selected light-emitting sub-portion ga. The plurality of third via holes K3 respectively reach the N-type gallium nitride portions 131 of the light-emitting sub-portions g.

As shown in FIGS. 3A and 3B, the cathode 161 is connected to the cathode transfer electrode 141 through the first via hole K1, and the anode 163 is connected to the conductive portion 1323 of the second selected light-emitting sub-portion gb through the transfer via hole K21. A first end of any one connection electrode 162 of the plurality of connection electrodes 162 is connected to the conductive portion 1323 of one light-emitting sub-portion g of the at least two light-emitting sub-portions g through the connection via hole K22, and a second end of the connection electrode 162 is connected to the N-type gallium nitride portion 131 of another light-emitting sub-portion g through the third via hole K3.

For example, as shown in FIGS. 3A and 3B, a material of the first passivation layer 15 includes, but is not limited to, an insulating material. The material of the first passivation layer 15 includes, but is not limited to, at least one of silicon nitride or silicon oxide.

The first passivation layer 15 covers the light-emitting layer 13 and the transfer layer 14, thereby providing an insulation barrier and achieving a protective effect for the light-emitting layer 13 and the transfer layer 14. The light-emitting portion G and the transfer layer 14 are connected to other structures through via holes (such as K1, K2 or K3) in the first passivation layer 15.

Moreover, the first passivation layer 15 partially fills the gap between two adjacent light-emitting sub-portions g, thus increasing the strength of the chip wafer unit 1 and avoiding the cracks in the gap between the light-emitting sub-portions g in the chip wafer unit 1.

As shown in FIGS. 3A, 3B, 4A, 4B and 4C, in the chip wafer unit 1, the N-type gallium nitride portions included in the plurality of first selected light-emitting sub-portions ga included in the plurality of light-emitting portions G 131 are common N-type gallium nitride portions, i.e., the first N-type gallium nitride patterns 1311. The first N-type gallium nitride pattern 1311 is electrically connected to the cathode transfer electrode 141, and the first N-type gallium nitride pattern 1311 is electrically connected to the cathode 161 through the cathode transfer electrode 141. The conductive portion 1323 of the second selected light-emitting sub-portion gb included in each light-emitting portion G is electrically connected to the anode 163.

In some examples, as shown in FIGS. 3A and 4A, each light-emitting portion G includes two light-emitting sub-portions g. The anode 163 is connected to the conductive portion 1323 of the second selected light-emitting sub-portion gb through the transfer via hole K21, and the conductive portion 1323 of the second selected light-emitting sub-portion gb is electrically connected to the P-type gallium nitride portion 1322. An end of the connection electrode 162 is connected to the N-type gallium nitride portion 131 of the second selected light-emitting sub-portion gb (for example, the second N-type gallium nitride pattern 1312) through the third via hole K3, and another end of the connection electrode 162 is connected to the N-type gallium nitride portion 131 of the first selected light-emitting sub-portion ga (for example, the first N-type gallium nitride pattern 1311) through the connection via hole K22. The N-type gallium nitride portion 131 of the first selected light-emitting sub-portion ga is connected to the cathode 161 through the cathode transfer electrode 141.

In this way, referring to FIGS. 3A and 4A, the anode 163, the P-type gallium nitride portion 1322 of the second selected light-emitting portion gb, the N-type gallium nitride portion 131 of the second selected light-emitting portion gb, the connection electrode 162, the P-type gallium nitride portion 1322 of the first selected light-emitting sub-portion ga, the N-type gallium nitride portion 131 of the first selected light-emitting sub-portion ga, the cathode transfer electrode 141, and the cathode 161 form a path of the series structure.

In some other examples, as shown in FIGS. 3B and 4B, each light-emitting portion G includes three light-emitting sub-portions g and two connection electrodes 162. The anode 163 is connected to the conductive portion 1323 of the second selected light-emitting sub-portion gb through the transfer via hole K21, and the conductive portion 1323 of the second selected light-emitting sub-portion gb is electrically connected to the P-type gallium nitride portion 1322. An end of one connection electrode 162 is connected to the N-type gallium nitride portion 131 of the second selected light-emitting sub-portion gb (for example, the second N-type gallium nitride pattern 1312) through one third via hole K3, and another end of the connection electrode 162 is connected to the conductive portion 1323 of the light-emitting sub-portion g through one connection via hole K22. The conductive portion 1323 of the light-emitting sub-portion g is electrically connected to the P-type gallium nitride portion 1322, and the N-type gallium nitride portion 1321 of the light-emitting sub-portion g (for example, the second N-type gallium nitride pattern 1312) is connected to an end of another connection electrode 162 through another third via hole K3, and another end of the another connection electrode 162 is connected to the N-type gallium nitride portion 131 of the first selected light-emitting sub-portion ga (for example, the first N-type gallium nitride pattern 1311) through another connection via hole K22. The N-type gallium nitride portion 131 of the first selected light-emitting sub-portion ga is connected to the cathode 161 through the cathode transfer electrode 141.

In this way, referring to FIGS. 3B and 4B, the anode 163, the P-type gallium nitride portion 1322 of the second selected light-emitting portion gb, the N-type gallium nitride portion 131 of the second selected light-emitting portion gb, one connection electrode 162, the P-type gallium nitride portion 1322 of the light-emitting sub-portion g, the N-type gallium nitride portion 131 of the light-emitting sub-portion g, another connection electrode 162, the P-type gallium nitride portion 1322 of the first selected light-emitting sub-portion ga, the N-type gallium nitride portion 131 of the first selected light-emitting sub-portion ga, the cathode transfer electrode 141, and the cathode 161 form a path of the series structure.

In yet some other examples, as shown in FIG. 4C, each light-emitting portion G includes four light-emitting sub-portions g and three connection electrodes 162. In this case, as for the method of forming a path for the series structure, reference is made to FIGS. 3B and 4C and the above description, which will not be repeated here.

It can be understood that when two light-emitting sub-portions g are connected through the connection electrode 162, two ends of the connection electrode 162 are respectively connected to the N-type gallium nitride portion 131 of one of the light-emitting sub-portions g and the P-type gallium nitride portion 1322 of another of the light-emitting sub-portions g, thereby realizing the series connection of the at least two light-emitting sub-portions g included in the light-emitting portion G.

The total working voltage of the light-emitting sub-portions g of a series structure is higher than the working voltage of a single light-emitting sub-portion g. It can be understood that, in this way, the working voltage of each light-emitting portion G in the chip structure 10 is high; correspondingly, the working voltage of the chip structure 10 is high. Therefore, compared with a chip structure that emits light of a single color, when the chip structure 10 provided in the embodiments of the present disclosure is applied to the display apparatus, the power consumption of the chip structure 10 accounts for a large proportion of the overall power consumption of the display apparatus, the current utilization rate of the chip structure 10 is improved, which is conducive to reducing the energy consumption of other structures in the chip structure 10 except for the light-emitting portions and reducing energy waste. This avoids the problem that in the display, the light-emitting power consumption of the chip structure accounts for a low proportion of the overall power consumption, and the current cannot be fully utilized, causing energy waste.

For example, the connection electrode 162 is made of a conductive material. The material of the connection electrode 162 includes, but is not limited to, at least one of gold, silver, copper, titanium, aluminum, molybdenum, nickel gold, or conductive silver glue.

Referring to FIGS. 3A and 3B, the connection electrodes 162 are provided; each connection electrode 162 connects two light-emitting sub-portions g, and further partially fills a gap between the two light-emitting sub-portions g; therefore, the strength of the chip wafer unit 1 is increased, which avoids the cracks in the gap between the light-emitting sub-portions g in the chip wafer unit 1.

As shown in FIGS. 4A, 4B and 4C, when the size of the chip wafer unit 1 remains unchanged, the number of light-emitting regions is increased, for example, by reducing the size of the cathode transfer electrode 141. Furthermore, the size of the cathode transfer electrode 141 needs to meet the set requirement; if the size of the cathode transfer electrode 141 is smaller than the set requirement, the cathode transfer electrode 141 cannot achieve the target effect; for example, the size of the cathode transfer electrode 141 is too small, leading to a large resistance value of the cathode transfer electrode 141, which will increase the power consumption of the chip structure except the light-emitting power consumption. It can be understood that when the light-emitting portion includes a large quantity of light-emitting sub-portions (for example, each light-emitting portion includes four or more light-emitting sub-portions), the size of the chip wafer unit needs to be increased while the size of the cathode transfer electrode 141 is reduced.

For example, when the number of light-emitting sub-portions g included in the light-emitting portion G of the chip wafer unit 1 is different, the size of the chip structure 10 is also different. It can be understood that the greater the number of light-emitting sub-portions g included in each light-emitting portion G, the larger the size of the chip structure 10. As for the size of the chip structure 10 when the number of light-emitting sub-portions g included in each light-emitting portion G in the chip structure 10 is different, reference is made to the above description of FIGS. 2A, 2B and 2C, and details will not be repeated here.

In some embodiments, as shown in FIGS. 1, 3A and 3B, the chip wafer unit 1 further includes: a second passivation layer 17 and a pad layer 18 stacked in the first direction X.

For example, as shown in FIGS. 3A and 3B, the second passivation layer 17 covers the electrode layer 16. The second passivation layer 17 includes: a fourth via hole K4 corresponding to the first via hole K1 and a plurality of fifth via holes K5 that are one-to-one opposite to the plurality of transfer via holes K21. The fourth via hole K4 reaches the cathode 161, and the fifth via hole K5 reaches the anode 163.

The second passivation layer 17 covers the cathode 161, connection electrodes 162, anodes 163, etc. included in the electrode layer 16, thereby achieving an insulation barrier effect and effectively preventing damage to the electrode layer 16 caused by collisions with external structures.

For example, as shown in FIGS. 3A and 3B, the second passivation layer 17 may be made of an insulating material. The material of the second passivation layer includes, but is not limited to, at least one of silicon nitride or silicon oxide.

Referring to FIGS. 3A and 3B, the second passivation layer 17 partially fills a gap between two adjacent light-emitting sub-portions g, and also covers side walls of the gap between two adjacent light-emitting sub-portions g., which can effectively reduce the sidewall effect and avoid light leakage and color interference of light emitted from the light-emitting sub-portions g. As a result, the light extraction effect of the chip structure 10 is improved.

For example, as shown in FIGS. 3A and 3B, the pad layer 18 includes: a first pad 181 and a plurality of second pads 182 in one-to-one correspondence with the plurality of anodes 163. The first pad 181 is connected to the cathode 161 through the fourth via hole K4, and the second pad 182 is connected to the anode 163 through the fifth via hole K5.

In some embodiments, as shown in FIG. 3A, a distance r6 between the first pad 181 and the second pad 182 is in a range of 73 μm to 77 μm.

As shown in FIG. 23, when the chip structure 10 is used in the display, the chip structure 10 is connected to an external structure (for example, a second substrate 20 with a circuit structure formed on its surface) through the pad layer 18. The pad layer 18 plays a connecting role, and also ensures that a certain spacing between the chip structure 10 and the external structure connected thereto can be maintained. In this way, a gap is formed between the chip structure 10 and the external structure, which facilitates the heat dissipation of the chip structure 10. Moreover, it avoids the problem of damage to the chip structure 10 due to contact between the external structure and another structure of the chip structure 10 except for the pad layer 18.

In some examples, as shown in FIGS. 2A, 2B and 2C, the chip wafer unit is in a shape of a rectangle, and the chip wafer unit 1 includes three light-emitting portions G.

In this case, the chip wafer unit 1 includes four pads, and the four pads include, for example, one first pad 181 and three second pads 182. The four pads are respectively located at the four corners of the chip wafer unit 1.

When the chip structure 10 is used in display, for example, a plurality of chip structures 10 are arranged in an array on a base substrate that has a circuit structure, and each chip structure 10 is electrically connected to the circuit structure through the pad layer 18. It can be understood that, in this way, the connection between the chip structure 10 and the base substrate has good stability.

For example, as shown in FIGS. 3A and 3B, the chip wafer unit 1 further includes a plurality of electrode pads 19. The plurality of electrode pads 19 are arranged corresponding to the cathode 161 and the plurality of anodes 163. For example, the first selected light-emitting sub-portion ga is connected to the cathode 161 through an electrode pad 19, and the second selected light-emitting sub-portion gb is connected to the anode 163 corresponding to the light-emitting portion G through another electrode pad 19.

By arranging the electrode pads 19, the connection between the first pad 181 and the cathode 161 has good stability, and the connection between the second pad 182 and the anode 163 has good stability. When the chip structure 10 is working, the working currents or electrical signals for driving the light-emitting portions G to work have good transmission effect. As a result, the connection stability of the circuits is improved, and the transmission stability of the electrical signals is improved.

In some embodiments, as shown in FIGS. 3A and 3B, the chip wafer unit 1 further includes a buffer layer 11 and a U-type gallium nitride layer 12 stacked in the first direction X. The U-type gallium nitride layer 12 is disposed between the buffer layer 11 and the light-emitting layer 13. The first passivation layer 15 further covers the U-type gallium nitride layer 12 and the buffer layer 11.

For example, as shown in FIGS. 3A and 3B, the U-type gallium nitride layer 12 is made of undoped gallium nitride (Undoped GaN or U-GaN for short).

By providing the U-type gallium nitride layer 12, the overflow electron flow can be effectively reduced, and the concentration of holes in each quantum well portion 1321 is increased. Therefore, the luminous intensity of the light-emitting sub-portion g is adjusted, and the light extraction effect of the chip structure 10 is improved.

In some embodiments of the present disclosure, the N-type gallium nitride portions 131 included in the chip wafer unit 1 includes first N-type gallium nitride patterns 1311 and a plurality of second N-type gallium nitride patterns 1312 that are independently separated from each other. It can be understood that in the embodiments of the present disclosure, the N-type gallium nitride portions are not designed as a whole layer structure, but includes a plurality of independent structures.

In some examples, the N-type gallium nitride portions are designed as a whole layer structure. In this case, the thickness of the buffer layer included in the chip wafer unit is in a range of 2 μm to 3 μm, for example. It can be understood that when the N-type gallium nitride portions are changed from the design of a whole layer structure to the design of multiple independently separated structures provided in some embodiments of the present disclosure, compared with a whole layer of N-type gallium nitride portions, part of support is lost at positions of gaps between the first N-type gallium nitride patterns 1311 and the plurality of second N-type gallium nitride patterns 1312. Therefore, the strength of the chip wafer unit 1 is reduced at those positions, leading to the risk of breakage.

In some embodiments, as shown in FIGS. 3A and 3B, a thickness of the buffer layer 11 in the first direction X is in a range of 4.5 μm to 5.5 μm.

By increasing the thickness of the buffer layer 11, the overall structural strength of the chip wafer unit 1 is increased, which avoids the problem of breakage at gaps between the first N-type gallium nitride pattern 1311 and the plurality of second N-type gallium nitride patterns 1312 in the chip wafer unit 1.

For example, as shown in FIGS. 3A and 3B, a thickness of the U-type gallium nitride layer 12 in the first direction X is in a range of 0.5 μm to 1.5 μm.

For example, as shown in FIGS. 3A and 3B, a thickness of the N-type gallium nitride portion 131 in the first direction X is in a range of 2 μm to 3 μm.

For example, as shown in FIGS. 3A and 3B, a thickness of the quantum well portion 1321 in the first direction X is in a range of 0.1 μm to 0.15 μm.

For example, as shown in FIGS. 3A and 3B, a thickness of the P-type gallium nitride portion 1322 in the first direction X is in a range of 0.1 μm to 0.15 μm.

By controlling the thickness of each functional layer/functional portion (such as the U-type gallium nitride layer 12, N-type gallium nitride portion 131, quantum well portion 1321, and P-type gallium nitride portion 1322), each functional layer/function portion achieves the effect of the design, and ensures that the overall size of the chip structure 10 (dimensions such as length, width, and thickness of the chip structure 10) is within a target range, thereby ensuring the miniaturization design of the chip structure 10.

In some embodiments, as shown in FIG. 3A, a distance r1 between boundaries of the N-type gallium nitride portion 131 and the P-type gallium nitride portion 1322 in the light-emitting sub-portion g is in a range of 9.5 μm to 10.5 μm.

By ensuring a certain difference in size between the N-type gallium nitride portion 131 and the P-type gallium nitride portion 1322 of each light-emitting sub-portion g, a position is reserved for the connection electrode 162 for connection, so that the effective connection between the connection electrode 162 and the N-type gallium nitride portion 131 of the light-emitting sub-portion g is guaranteed. Moreover, it effectively avoids that the connection electrode 162 is in contact with the P-type gallium nitride portion 1322, leading to a short circuit problem in the light-emitting portion.

In some embodiments, as shown in FIG. 3A, a distance r2 between a boundary of the second N-type gallium nitride pattern 1312 and the third via hole K3 is greater than or equal to 5 μm.

By controlling the position of the third via hole K3, the effective connection between the connection electrode 162 and the second N-type gallium nitride pattern 1312 is guaranteed, which avoids the problem that the distance between the third via hole K3 and the boundary of the second N-type gallium nitride pattern 1312 is too small, leading to the separation between the connection electrode 162 and the second N-type gallium nitride pattern 1312.

In some embodiments, as shown in FIGS. 3A, 4A, 4B and 4C, a distance r3 between the first N-type gallium nitride pattern 1311 and any one of the plurality of second N-type gallium nitride patterns 1312 is greater than or equal to 6 μm. A distance r4 between any two of the plurality of second N-type gallium nitride patterns 1312 is greater than or equal to 6 μm.

Each light-emitting portion G includes at least two light-emitting sub-portions g forming a series structure, and the plurality of light-emitting portions G emit light independently. By ensuring the distance between the second N-type gallium nitride pattern 1312 and the remaining second N-type gallium nitride pattern 1312 and the distance between the second N-type gallium nitride pattern 1312 and the first N-type gallium nitride pattern 1311, the light extraction effect of the chip structure 10 is guaranteed.

In some embodiments, as shown in FIGS. 3A and 3B, a distance r5 between the cathode transfer electrode 141 and the quantum well portion 1321 is greater than or equal to 8 μm.

By controlling the distance between the cathode transfer electrode 141 and the quantum well port 1321, it avoids a short circuit problem caused by the contact between the cathode transfer electrode 141 and the light-emitting functional portion 132.

In some embodiments, as shown in FIGS. 3A and 3B, aperture sizes of the first via hole K1, second via holes K2 (e.g., the transfer via hole K21 and the connection via hole K22), third via hole K3, fourth via hole K4, and fifth via hole K5 are each in a range of 4.5 μm to 5.5 μm.

By controlling the sizes of via holes in the first passivation layer 15 and the second passivation layer 17, the insulation barrier effect of the passivation layers (e.g., the first passivation layer 15 and/or the second passivation layer 17) is ensured; at the same time, the effective connection between the electrode layer 16 and the light-emitting layer 13 is achieved.

In some embodiments, as shown in FIGS. 1 and 5, the color conversion substrate unit 2 includes: a first substrate 21, a color filter layer 22 disposed on a side of the first substrate 21 facing the chip wafer unit 1, a definition dam layer 23 disposed on a side of the color filter layer 22 away from the first substrate 21, a color conversion layer 24, an encapsulation layer 25 and a bonding layer 26. The color filter layer 22 includes a black matrix 221 and a plurality of filter portions 222 defined by the black matrix 221. The plurality of filter portions 222 are in one-to-one correspondence with the plurality of light-emitting portions G. The definition dam layer 23 includes a plurality of opening regions Q, and the plurality of opening regions Q are in one-to-one correspondence with the plurality of filter portions 222.

As shown in FIG. 5, the color conversion layer 24 is disposed in the plurality of opening regions Q. The color conversion layer 24 includes color conversion portions and a filling portion. The filling portion is disposed in a third opening region. The encapsulation layer 25 covers the definition dam layer 23 and the color conversion layer 24. The bonding layer 26 is disposed on a side of the encapsulation layer 25 away from the first substrate 21.

For example, as shown in FIG. 5, the first substrate 21 includes but is not limited to any one of a glass substrate, a quartz substrate, a plastic substrate, a sapphire substrate or a silicon-based substrate.

For example, as shown in FIG. 5, a thickness h1 of the first substrate 21 is in a range of 60 μm to 200 μm.

For example, as shown in FIG. 5, the filter portion 222 is a color filter sheet or a color filter film.

As shown in FIG. 1, light emitted by the light-emitting portion G sequentially passes through the filter portion 222 and the color conversion layer 24 and then exits. By providing the filter portions 222, the color gamut of light emitted by the light-emitting portions G is improved, and in turn the color gamut of light emitted by the chip structure 10 is improved.

In some embodiments, as shown in FIG. 5, the plurality of filter portions 222 include: a first color filter portion arranged corresponding to the first light-emitting portion, a second color filter portion arranged corresponding to the second light-emitting portion, and a third color filter portion arranged corresponding to the third light-emitting portion. The plurality of opening regions include: a first opening region arranged corresponding to the first light-emitting portion, a second opening region arranged corresponding to the second light-emitting portion, and a third opening region arranged corresponding to the third light-emitting portion.

In some embodiments, as shown in FIG. 5, the color conversion layer 24 includes a first color conversion portion disposed in the first opening region and a second color conversion portion disposed in the second opening region. The first color conversion portion includes, but is not limited to, a first quantum dot conversion portion or a first fluorescent color conversion portion. The second color conversion portion includes, but is not limited to, a second quantum dot conversion portion or a second fluorescent color conversion portion.

For example, as shown in FIGS. 2A, 2B and 2C, the first light-emitting portion G1, the second light-emitting portion G2 and the third light-emitting portion G3 all emit blue light. The first color conversion portion is configured to convert the color of the light emitted by the first light-emitting portion G1. The second color conversion portion is configured to convert the color of the light emitted by the second light-emitting portion G2. The blue light emitted by the first light-emitting portion G1 is converted into, for example, red light after passing through the first color conversion portion and then exits. The blue light emitted by the second light-emitting portion G2 is converted into, for example, green light after passing through the second color conversion portion and then exits.

It can be understood that the first color conversion portion and the second color conversion portion may also be made of other materials, as long as the color conversion function can be realized. This is only used as an illustration of a possible implementation and is not intended to limit the present disclosure.

In some embodiments, the filling portion includes, but is not limited to, a scattering particle portion or a transparent glue.

The filling portion is configured to fill a third opening region, resulting in a flat filling of the third opening region. A color of light emitted by the third light-emitting portion does not change after passing through the filling portion. Blue light emitted by the third light-emitting portion remains blue light after passing through the filling portion. After passing through the color conversion layer 24, the blue light emitted by

each light-emitting portion G remains blue light, or is converted into red light or green light. A single chip structure 10 can emit light of a plurality of colors, such as blue light, red light or green light.

It can be understood that the filling portion may also be made of other materials, as long as the filling effect of the third opening region can be achieved and the color of the light will not be changed when the light passes through the filling portion. This is only used as an illustration of a possible implementation and is not intended to limit the present disclosure.

In another aspect, a method of manufacturing a chip structure is provided. The method is used to manufacture the chip structure 10 as described in any one of the above embodiments. As shown in FIG. 6, the method of manufacturing the chip structure includes steps S1 to S4.

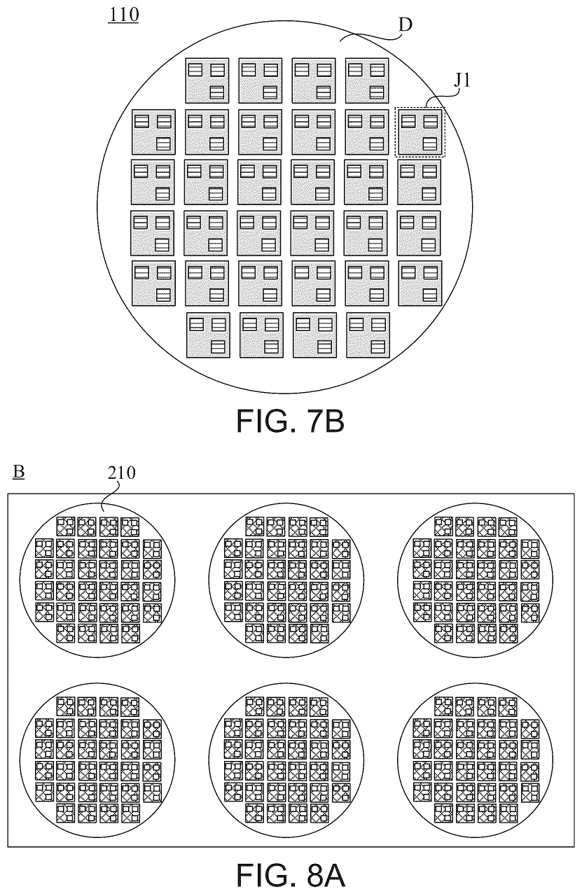

In S1, a first initial wafer A is formed. As shown in FIG. 7A, the first initial wafer A includes a plurality of initial chip wafer units 110.

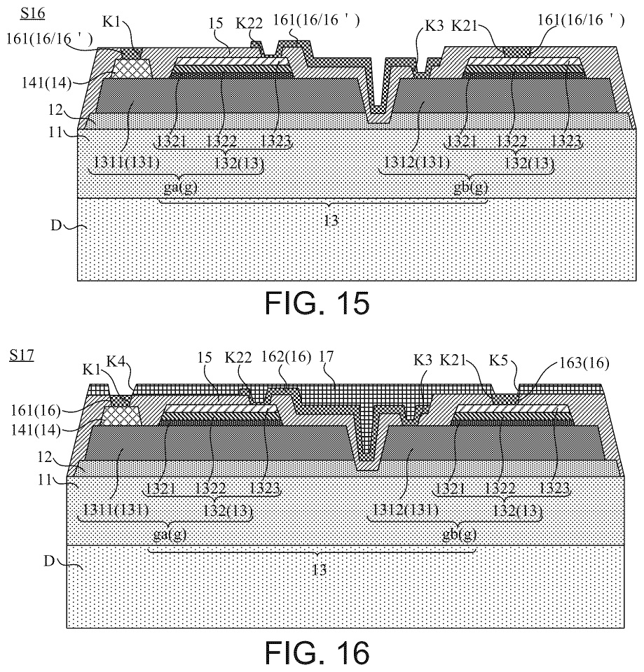

As shown in FIGS. 7B and 15, the initial chip wafer unit 110 includes: an initial substrate D, and an initial light-emitting layer 13′ and an initial electrode layer 16′ that are sequentially stacked on a first surface of the initial substrate D in the first direction X. The initial light-emitting layer 13′ includes multiple light-emitting portions G. As shown in FIG. 15, each light-emitting portion G includes at least two light-emitting sub-portions g.

As shown in FIGS. 7B and 15, the initial chip wafer unit 110 also includes a plurality of chip structure regions J1, and each chip structure region J1 includes a chip wafer unit 1. Each chip wafer unit 1 includes a plurality of light-emitting portions G, and each light-emitting portion G includes at least two light-emitting sub-portions g. Each chip structure 10 further includes a cathode 161, a plurality of connection electrodes 162, and a plurality of anodes 163 in one-to-one correspondence with the plurality of light-emitting portions G.

For example, as shown in FIG. 7A, a shape of the initial chip wafer unit 110 includes, but is not limited to, a circle.

For example, as shown in FIG. 7B, the initial chip wafer unit 110 includes a plurality of chip wafer units 1, and each chip wafer unit 1 is located in a chip structure region J1.

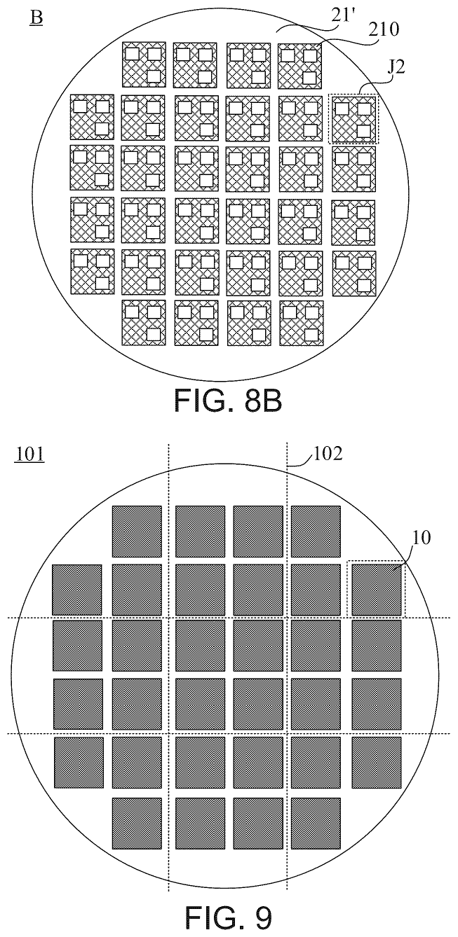

In S2, a second initial wafer B is formed. As shown in FIG. 8A, the second initial wafer B includes a plurality of initial color conversion substrate units 210.

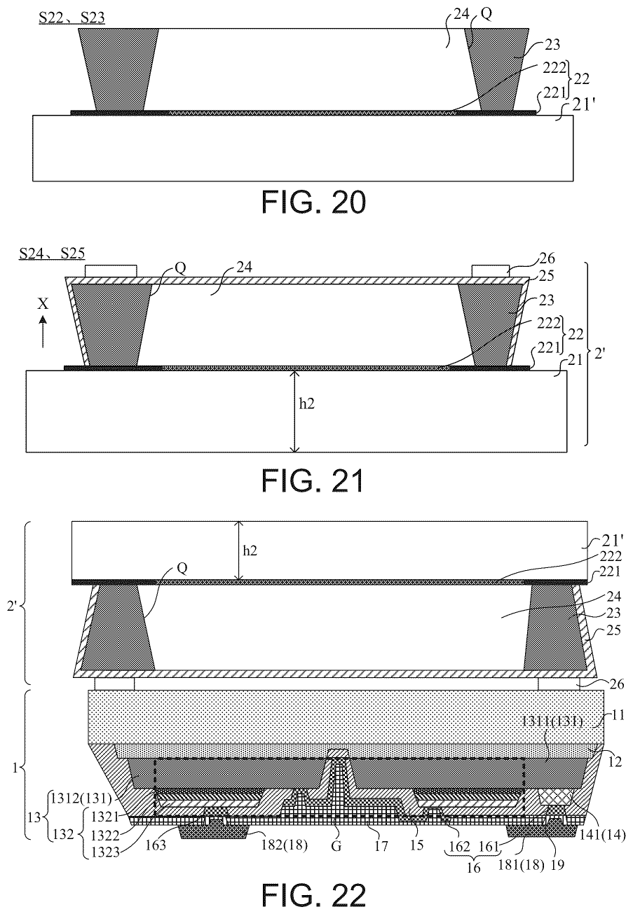

As shown in FIGS. 8B and 20, the initial color conversion substrate unit 210 includes: an initial first substrate 21′, and an initial definition dam layer 23′ and an initial color conversion layer 24′ that are disposed on a side of the initial first substrate 21′. The initial color conversion substrate unit 210 further includes color conversion structure regions J2, and each color conversion structure region J2 includes a color conversion substrate unit. Each color conversion structure region J2 includes a plurality of color conversion regions in one-to-one correspondence with the multiple light-emitting portions G. The initial color conversion layer 24′ includes a plurality of color conversion portions, and a color conversion portion is arranged in a color conversion region.

For example, as shown in FIGS. 7A and 8A, a shape of the second initial wafer B is the same as a shape of the first initial wafer A. The shape of the second initial wafer B includes, but is not limited to, a circle or a rectangle.

For example, as shown in FIGS. 7A and 8A, a shape of the initial color conversion substrate unit 210 is the same as the shape of the initial chip wafer unit 110. The shape of the initial color conversion substrate unit 210 includes, but is not limited to, a rectangle or a circle.

For example, as shown in FIG. 8B, the initial color conversion substrate unit 210 includes a plurality of color conversion substrate units 2, each color conversion substrate unit is located in a color conversion structure region J2.

In S3, the second initial wafer B is arranged on a light-exit side of the first initial wafer A for assembly, to obtain a chip wafer structure 101. As shown in FIG. 9, the chip wafer structure 101 includes a plurality of chip structures 10.

For example, a size of the first initial wafer A is 4 inches or 6 inches; and a size of the second initial wafer B is the same as the size of the first initial wafer A.

For example, in step S3, the first initial wafer A is assembled with the second initial wafer B through a bonding process. During the assembling process, the plurality of chip structure regions J1 included in the initial chip wafer unit 110 are in one-to-one correspondence with the plurality of color conversion structure regions J2 included in the initial color conversion substrate unit 210. Moreover, the plurality of color conversion regions included in each color conversion structure region J2 are in one-to-one correspondence with a plurality of light-emitting portions G included in the plurality of chip structure regions J1.

In S4, as shown in FIG. 9, the chip wafer structure 101 is cut along cutting lines 102 to obtain the plurality of chip structures 10.

For example, as shown in FIGS. 7B, 8B and 9, when cutting the chip wafer structure 101, the chip wafer structure is cut along border lines of each chip structure region J1 or each color conversion structure region J2.

It should be noted that the order of step S1 and step S2 is not limited, which is only used as an illustration of a possible implementation.

In order to clearly describe the method of manufacturing the chip structure 10, the process of manufacturing one chip structure 10 will be described below as an example. It can be understood that the method of manufacturing the chip structure 10 is to first form the chip wafer structure 101 including a plurality of chip structures 10 arranged in an array, and then cut the chip wafer structure 101 to obtain the plurality of chip structures 10.

The detailed implementation of each step in the method of manufacturing the chip structure 10 will be introduced below. The chip structure 10 formed according to the embodiments is the chip structure 10 shown in FIG. 1.

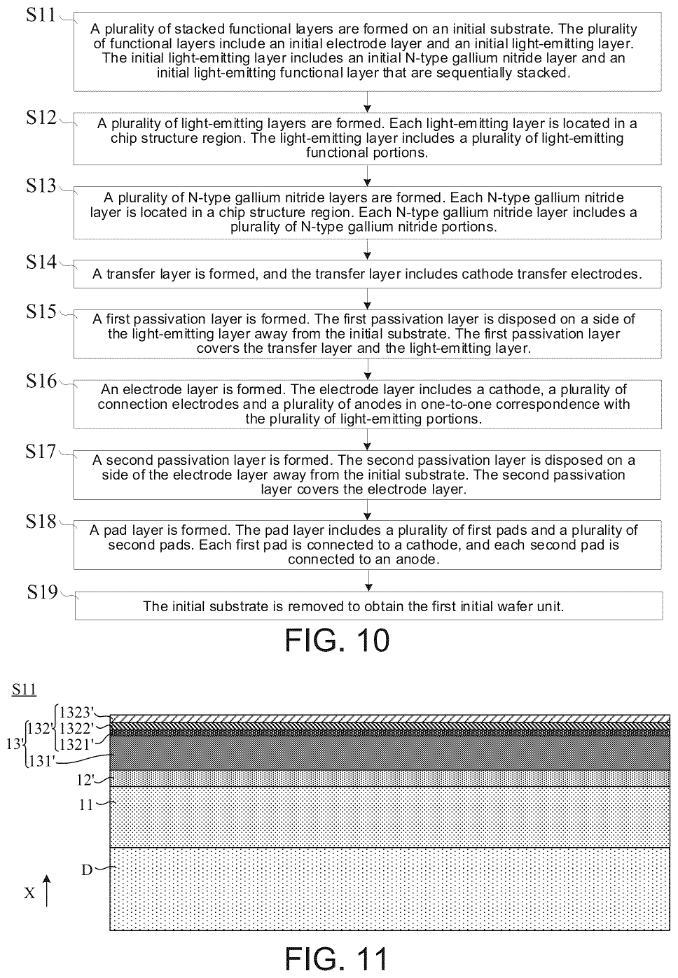

In some embodiments, as shown in FIG. 10, step S1 includes steps S11 to S19.

In S11, as shown in FIG. 11, a plurality of stacked functional layers are formed on the initial substrate D. The plurality of functional layers include an initial electrode layer 16′ and an initial light-emitting layer 13′. The initial light-emitting layer 13′ includes an initial N-type gallium nitride layer 131′ and an initial light-emitting functional layer 132′ that are sequentially stacked.

For example, as shown in FIG. 11, the initial substrate D is a silicon-based substrate or a sapphire substrate.

For example, as shown in FIG. 11, the plurality of functional layers are formed using a metal sputtering process or a chemical deposition process.

In some embodiments, as shown in FIG. 11, the initial light-emitting functional layer 132′ includes an initial quantum well layer 1321′, an initial P-type gallium nitride layer 1322′, and an initial conductive layer 1323′ that are sequentially stacked.

For example, a material of the initial conductive layer 1323′ includes, but is not limited to, indium tin oxide (ITO).

For example, each of the plurality of light-emitting portions G is configured to emit light of one color of a plurality of colors.

In some examples, the plurality of light-emitting portions G all emit light of the same color.

For example, light of a plurality of colors includes, but is not limited to, blue light.

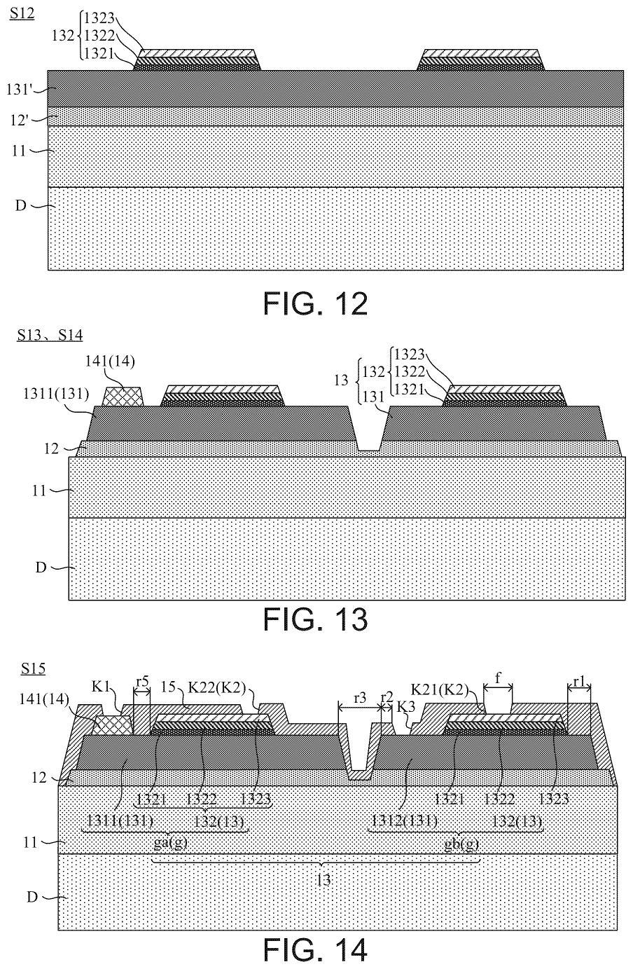

In S12, as shown in FIGS. 7B and 12, a plurality of light-emitting layers 13 are formed, and each light-emitting layer 13 is located in a chip structure region J1. The light-emitting layer 13 includes a plurality of light-emitting functional portions 132. Each light-emitting functional portion 132 includes a quantum well portion 1321, a P-type gallium nitride portion 1322, and a conductive portion 1323 that are sequentially stacked.

For example, as shown in FIGS. 11 and 12, the initial light-emitting functional layer 132′ is patterned using a photolithography process, so as to form the plurality of light-emitting functional portions 132.

For example, after step S12, the method further includes forming an initial reflective metal layer. The initial reflective metal layer is formed on a side of the light-emitting layer away from the initial substrate.

In some examples, the initial reflective metal layer is patterned to obtain a plurality of reflective portions in one-to-one correspondence with the plurality of light-emitting functional portions 132.

A reflective metal layer of each of the plurality of initial chip wafer units 110 is obtained.

For example, the initial reflective metal layer is deposited through a deposition process.

For example, the reflective metal layer is made of ITO—Ag—ITO. The reflective metal layer has the function of reflecting light and may improve the light extraction rate of the chip structure, thereby improving the light extraction effect of the chip structure.

For example, as shown in FIG. 12, the quantum well portion 1321 is a blue quantum well, and the light-emitting functional portion 132 including a blue quantum well emits blue light.

For example, as shown in FIGS. 11 and 12, the initial quantum well layer 1321′ is patterned through a photolithography process or laser etching to obtain a plurality of quantum well portions 1321.

For example, as shown in FIGS. 11 and 12, the initial P-type gallium nitride layer 1322′ is patterned through a photolithography process or laser etching to obtain a plurality of P-type gallium nitride portions 1322.

For example, as shown in FIGS. 11 and 12, the initial conductive layer 1323′ is patterned through a photolithography process or laser etching to obtain a plurality of conductive portions 1323.

For example, as shown in FIG. 14, a distance r1 between boundaries of the N-type gallium nitride portion and the P-type gallium nitride portion included in each light-emitting functional portion is in a range of 9.5 μm to 10.5 μm.

In S13, as shown in FIGS. 7B and 13, a plurality of N-type gallium nitride layers are formed, and each N-type gallium nitride layer is located in a chip structure region

J1. Each N-type gallium nitride layer includes a plurality of N-type gallium nitride portions 131.

For example, as shown in FIGS. 12 and 13, the initial N-type gallium nitride layer 131′ is patterned through a photolithography process or laser etching to obtain a plurality of N-type gallium nitride portions 131.

For example, as shown in FIG. 13, the plurality of N-type gallium nitride portions 131 include a plurality of first N-type gallium nitride patterns 1311 and a plurality of second N-type gallium nitride patterns 1312.

In S14, as shown in FIG. 13, a transfer layer 14 is formed. The transfer layer 14 includes cathode transfer electrodes 141.

For example, as shown in FIG. 13, a plurality of light-emitting sub-portions g include a first selected light-emitting sub-portion ga, and an N-type gallium nitride portion 131 of a first selected light-emitting sub-portion ga (for example, a first N-type gallium nitride pattern 1311) is connected to a cathode transfer electrode 141. The N-type gallium nitride portion 131 included in the first selected light-emitting sub-portion ga is the first N-type gallium nitride pattern 1311, and N-type gallium nitride portions 131 included in the remaining light-emitting sub-portions g except for the first selected light-emitting sub-portion ga are second N-type gallium nitride patterns 1312.

For example, as shown in FIG. 14, a distance r5 between the cathode transfer electrode 141 and the quantum well portion 1321 is greater than or equal to 8 um.

In some examples, as shown in FIG. 13, an initial transfer layer 14′ is formed using a metal sputtering process, a chemical deposition process or an evaporation process. The initial transfer layer 14′ includes a plurality of transfer layers 14, and each transfer layer 14 is located in a chip structure region J1. Then, the initial transfer layer 14′ is patterned through a photolithography process to obtain the transfer layers 14.

In some other examples, the transfer layers are formed using a lift-off process. For example, a patterned lift-off structure is firstly formed, and the initial transfer layer 14′ is formed on a side of the lift-off structure away from the initial substrate using an evaporation process; then, the lift-off structure is removed to obtain the transfer layers 14.

It can be understood that at the same time as removing the lift-off structure, a part of the initial transfer layer 14′ covering the lift-off structure will be removed along with the lift-off structure; the cathode transfer electrodes 141 are retained on a side of the initial substrate D; and when the transfer layers 14 are formed, a plurality of cathode transfer electrodes 141 in each transfer layer 14 are formed simultaneously.

For example, as shown in FIG. 13, the transfer layer 14 is made of a conductive material. The material of the transfer layer 14 includes, but is not limited to, at least one of gold, silver, lead, tin, copper, titanium, aluminum, molybdenum, nickel gold, or conductive silver glue.

For example, as shown in FIG. 13, the cathode transfer electrode 141 is provided corresponding to the first N-type gallium nitride pattern 1311 and is located on a side of the first N-type gallium nitride pattern 1311 away from the initial substrate.

For example, as shown in FIGS. 4A, 4B, 4C and 13, a size of the cathode transfer electrode 141 is less than or equal to a size of the first N-type gallium nitride pattern 1311. A boundary of an orthographic projection of the first N-type gallium nitride pattern 1311 on the initial substrate D surrounds a boundary of an orthographic projection of the cathode transfer electrode 141 on the initial substrate D.

In S15, as shown in FIG. 14, a first passivation layer 15 is formed. The first passivation layer 15 is disposed on a side of the light-emitting layer 13 away from the initial substrate D. The first passivation layer 15 covers the transfer layer 14 and the light-emitting layer 13.

An initial first passivation layer includes a plurality of first via holes K1, a plurality of second via holes K2, and a plurality of third via holes K3. Each first via hole K1 is arranged corresponding to a first selected light emitting sub-portion ga. The plurality of first via holes K1 respectively reach the cathode transfer electrodes 141.

Each second via hole K2 is arranged corresponding to a light-emitting sub-portion g, and the plurality of second via holes K2 respectively reach the conductive portions 1323. Each third via hole K3 is arranged corresponding to a light-emitting sub-portion g except for the first selected light-emitting sub-portions ga, and the plurality of third via holes K3 respectively reach the N-type gallium nitride portions 131 of the light-emitting sub-portions g.

For example, as shown in FIG. 14, a material of the first passivation layer 15 includes, but is not limited to, an insulating material. The material of the first passivation layer includes but is not limited to at least one of silicon nitride or silicon oxide.

For example, in step S15, an initial first passivation layer is firstly formed using a chemical deposition process, and then a plurality of via holes are formed in the initial first passivation layer through a photolithography process, so that the first passivation layer is formed. As shown in FIG. 14, the plurality of via holes include first via holes K1, second via holes K2 (such as a transfer via hole K21 and a connection via hole K22), and a third via hole K3.

For example, as shown in FIG. 14, aperture sizes f of the first via hole K1, second via holes K2 (e.g., the transfer via hole K21 and the connection via hole K22), and third via hole K3 are each in a range of 4.5 μm to 5.5 μm.

For example, as shown in FIG. 14, a distance r2 between a boundary of the second N-type gallium nitride pattern 1312 and the third via hole K3 is greater than or equal to 5 μm.

For example, as shown in FIG. 14, a distance r3 between the first N-type gallium nitride pattern 1311 and any one of the plurality of second N-type gallium nitride patterns 1312 is greater than or equal to 6 μm.

For example, as shown in FIGS. 4A, 4B, and 4C, a distance r4 between any two of the plurality of second N-type gallium nitride patterns 1312 is greater than or equal to 6 μm.

For example, as shown in FIG. 14, the first passivation layer 15 partially fills the gap between two adjacent light-emitting sub-portions g, thus increasing the strength of the chip wafer unit 1 and avoiding the cracks in the gap between the light-emitting sub-portions g in the chip wafer unit 1.

In S16, as shown in FIG. 15, the electrode layer 16 is formed. The electrode layer 16 includes a cathode 161, a plurality of connection electrodes 162 and a plurality of anodes 163 in one-to-one correspondence with the plurality of light-emitting portions G.

For example, the electrode layer 16 is made of a conductive material. The material of the electrode layer 16 includes, but is not limited to, at least one of gold, silver, copper, titanium, aluminum, molybdenum, nickel gold, or conductive silver glue.

For example, the electrode layer 16 is formed using a lift-off process. For example, a patterned electrode lift-off structure is firstly formed, and the initial electrode layer 16′ is formed on a side of the electrode lift-off structure away from the initial substrate D using an evaporation process; the initial electrode layer 16′ includes a plurality of electrode layers 16, and each electrode layer 16 is located in a chip structure region J1; then, the electrode lift-off structure is removed to obtain the electrode layers 16.

It can be understood that at the same time as removing the electrode lift-off structure, a part of the initial electrode layer 16′ covering the electrode lift-off structure will be removed along with the electrode lift-off structure; the cathodes 161, connection electrodes 162, and the anodes 163 are retained on a side of the initial substrate D; and when the electrode layers 16 are formed, a plurality of cathodes 161, connection electrodes 162, and anodes 163 in all electrode layers 16 are formed simultaneously.

For example, each light-emitting portion G includes n light-emitting sub-portions, and the n light-emitting sub-portions are sequentially connected through (n-1) connection electrodes 162.

Among the two light-emitting sub-portions g connected by the connection electrode 162, an end of the connection electrode 162 is connected to the N-type gallium nitride portion 131 of one light-emitting sub-portion g, and another end of the connection electrode 162 is connected to the conductive portion 1323 of another light-emitting sub-portion g. The conductive portion 1323 of the light-emitting sub-portion g is electrically connected to the P-type gallium nitride portion 1322. The two light-emitting sub-portions g connected through the connection electrode 162 are connected in series through the connection electrode 162. The n light-emitting sub-portions g in each light-emitting portion G are sequentially connected in series through the (n-1) connection electrodes to form a light-emitting portion of a series structure.

In the light-emitting portion G of a series structure, the first selected light-emitting sub-portion ga and the second selected light-emitting sub-portion gb, which are each located at an end of the series structure, are connected to the cathode 161 and the anode 163, respectively. The N-type gallium nitride portion 131 (for example, the first N-type gallium nitride pattern 1311) of the first selected light-emitting sub-portion ga is connected to the cathode 161 through the cathode transfer electrode 141, and the P-type gallium nitride portion 1322 of the second selected light-emitting sub-portion gb is connected to the anode 163 through the conductive portion 1323.

In this way, compared with a single light-emitting sub-portion g serving as a single light-emitting portion G, a plurality of light-emitting sub-portions g are connected in series to form a light-emitting portion G, which has a higher working voltage. Correspondingly, the light-emitting portion G has a higher power consumption. Therefore, the proportion of the power consumption of the chip structure 10 for emitting light in the overall power consumption of the chip structure 10 is increased, the light-emitting effect of the chip structure 10 is improved, the power consumption loss is reduced, and energy waste is reduced.

In S17, as shown in FIG. 16, a second passivation layer 17 is formed. The second passivation layer 17 is disposed on a side of the electrode layer 16 away from the initial substrate, and the second passivation layer 17 covers the electrode layer 16.

The second passivation layer 17 includes a plurality of fourth via holes K4 that are in one-to-one correspondence with the plurality of first via holes K1 and a plurality of fifth via holes K5 that are in one-to-one correspondence with a plurality of transfer via holes K21.

For example, aperture sizes of the fourth via hole K4 and the fifth via hole K5 are each in a range of 4.5 μm to 5.5 μm.

For example, the second passivation layer 17 is formed using a chemical deposition process.

For example, a material of the second passivation layer 17 includes, but is not limited to, an insulating material. The material of the second passivation layer 17 includes, but is not limited to, at least one of silicon nitride or silicon oxide.

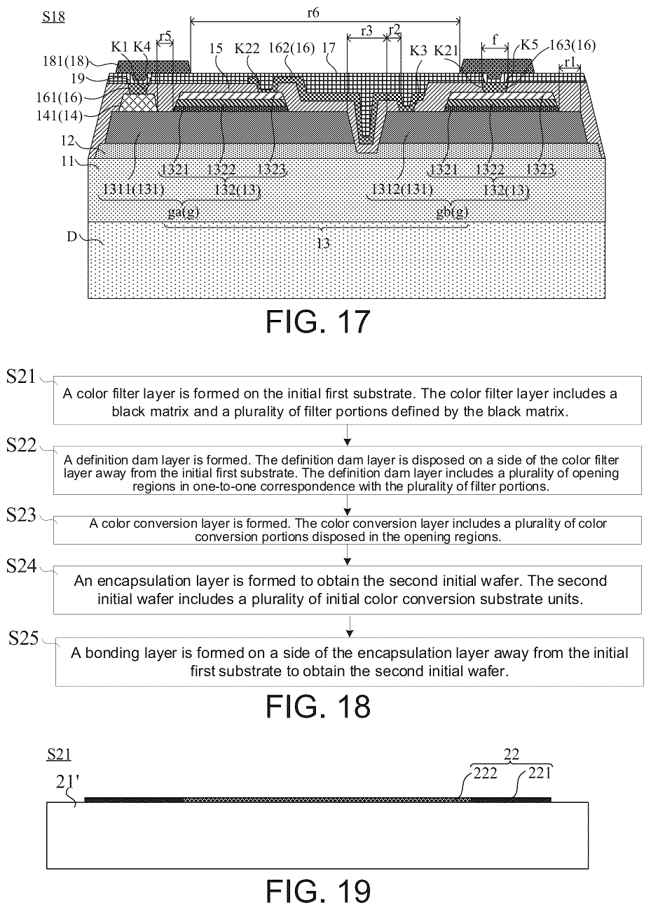

In S18, as shown in FIG. 17, a pad layer 18 is formed. The pad layer 18 includes a plurality of first pads 181 and a plurality of second pads 182. Each first pad 181 is connected to a cathode 161 through a fourth via hole K4, and each second pad 182 is connected to an anode 163 of a plurality of anodes 163 through a fifth via hole K5.

For example, the pad layer 18 is formed using a lift-off process. For example, a patterned pad lift-off structure is firstly formed, and an initial pad layer 18′ is formed on a side of the pad lift-off structure away from the initial substrate using an evaporation process; the initial pad layer 18′ includes a plurality of pad layers 18, and each pad layer 18 is located in a chip structure region J1; then, the pad lift-off structure is removed to obtain the pad layers.

It can be understood that at the same time as removing the pad lift-off structure, a part of the initial pad layer 18′ covering the pad lift-off structure will be removed along with the pad lift-off structure; the first pads 181 and the second pads 182 are retained on a side of the initial substrate D; and when the pad layers 18 are formed, a first pad 181 and a plurality of second pads 182 included in each pad layer 18 are formed simultaneously.

For example, the pad layer is made of a conductive material. The material of the pad layer includes, but is not limited to, at least one of gold, silver, lead, tin, copper, titanium, aluminum, molybdenum, nickel gold, or conductive silver glue.

For example, as shown in FIG. 17, a distance r6 between the first pad 181 and the second pad 182 is in a range of 73 μm to 77 μm.

In S19, the initial substrate D is removed to obtain the first initial wafer A.

In some embodiments, as shown in FIGS. 11 to 17, in step S11, a plurality of functional layers further include a buffer layer 11 and a U-type gallium nitride layer 12 sequentially stacked. The U-type gallium nitride layer 12 is located on a side of the initial light-emitting functional layer 13′ close to the initial substrate.

By providing the U-type gallium nitride layer 12, the overflow electron flow can be effectively reduced, and the concentration of holes in each quantum well portion is increased. Therefore, the luminous intensity of the light-emitting sub-portion is adjusted, and the light extraction effect of the chip structure is improved.

For example, a thickness of the buffer layer 11 is in a range of 4.5 μm to 5.5μm.

In some examples, the thickness of the buffer layer 11 is in a range of 2 μm to 3 μm. In some embodiments of the present disclosure, the overall strength of the chip wafer unit 1 is increased by increasing the thickness of the buffer layer 11, so as to avoid the problem of cracks in gaps between N-type gallium nitride portions 131 of the first initial wafer A (for example, gaps between N-type gallium nitride portions 131 included in each initial chip wafer unit 110 among two adjacent initial chip wafer units 110, and gaps between first N-type gallium nitride patterns 1311 and a plurality of second N-type gallium nitride patterns 1312 in the same chip structure) after the initial substrate D is removed.

In some embodiments, as shown in FIG. 18, step S20 includes steps S21 to S25.

In S21, as shown in FIG. 19, a color filter layer 22 is formed on the initial first substrate 21′. The color filter layer 22 includes a black matrix 221 and a plurality of filter portions 222 defined by the black matrix 221.

For example, a filter portion 222 is located in a color conversion region, and each filter portion 222 is arranged corresponding to at least one light-emitting portion G.

For example, the color filter layer 22 is formed using processes such as coating, exposure, development, and post-baking.

For example, the black matrix 221 and the plurality of filter portions 222 defined by the black matrix 221 are formed using processes such as coating, exposure, development, and post-baking.

For example, the plurality of light-emitting portions G include a first light-emitting portion G1, a second light-emitting portion G2, and a third light-emitting portion G3. The plurality of filter portions include a first filter portion arranged corresponding to a first light-emitting portion, a second filter portion arranged corresponding to a second light-emitting portion, and a third filter portion arranged corresponding to a third light-emitting portion.

For example, the first filter portion is a red filter portion, the second filter portion is a green filter portion, and the third filter portion is a blue filter portion.

For example, the filter portion 222 is a color filter sheet or a color filter film.

For example, the first substrate includes, but is not limited to, a glass substrate, a quartz substrate, a plastic substrate, a sapphire substrate, or a silicon-based substrate.

In the chip structure, light emitted by the light-emitting portion G sequentially passes through the filter portion 222 and the color conversion layer 24 and then exits. By providing the filter portions 222, the color gamut of light emitted by the light-emitting portions G is improved, and in turn the color gamut of light emitted by the chip structure 10 is improved.

In S22, as shown in FIG. 20, a definition dam layer 23 is formed. The definition dam layer 23 is disposed on a side of the color filter layer 22 away from the initial first substrate 21′. The definition dam layer 23 includes a plurality of opening regions Q in one-to-one correspondence with the plurality of filter portions 222.

For example, as shown in FIG. 20, the definition dam layer 23 is formed using processes such as coating, exposure, development, and post-baking.

For example, the plurality of opening regions Q include a first opening region arranged corresponding to a first filter portion, a second opening region arranged corresponding to a second filter portion, and a third opening region arranged corresponding to a third filter portion.

In S23, as shown in FIG. 20, the color conversion layer 24 is formed. The color conversion layer 24 includes a plurality of color conversion portions disposed in the opening regions Q.

For example, as shown in FIG. 20, the color conversion layer 24 is formed in the opening regions using processes such as coating, exposure, development, and post-baking or using inkjet printing process.

For example, a first quantum dot conversion portion is formed in the first opening region. The first quantum dot conversion portion uses, for example, red quantum dot luminescent material or red fluorescent material.

For example, a second quantum dot conversion portion is formed in the second opening region. The second quantum dot conversion portion uses, for example, green quantum dot luminescent material or green fluorescent material.

It should be noted that the materials of the first quantum dot conversion portion and the second quantum dot conversion portion only need to be able to realize the color conversion function. This is only used as an illustration of a possible implementation and is not intended to limit the present disclosure.

For example, a scattering particle portion is formed in the third opening region. The scattering particle portion uses, for example, scattering particles.

In S24, as shown in FIG. 21, an encapsulation layer 25 is formed to obtain the second initial wafer B. As shown in FIG. 8A, the second initial wafer B includes a plurality of initial color conversion substrate units 210.

For example, the encapsulation layer 25 is deposited on a side of the color conversion layer away from the first substrate using a chemical vapor deposition (CVD) process. The encapsulation layer 25 covers the color conversion layer 24 and the definition dam layer 23.

By providing the encapsulation layer 25, it may be possible to effectively avoid that the color conversion layer 24 is corroded by water and oxygen or mechanically damaged when being exposed to the air for a long time, which affects the color conversion effect of the color conversion layer 24, and in turn improve the working stability of the color conversion layer 24 and improve the working stability of the chip structure 10. In addition, the color conversion layer 24 has good luminous efficiency and heat dissipation environment, so that the service life of the color conversion layer 24 is improved, and the service life of the chip structure 10 is increased.

In some embodiments, as shown in FIG. 18, after step S24, the method further includes S25.

In S25, as shown in FIG. 21, a bonding layer 26 is formed on a side of the encapsulation layer 25 away from the initial first substrate 21′ to obtain the second initial wafer B.

For example, as shown in FIG. 21, the bonding layer 26 is an adhesive bonding layer.

For example, as shown in FIG. 21, an initial bonding layer 26′ is formed using a film forming process, and the initial bonding layer 26′ is patterned to obtain a plurality of bonding layers 26. Each bonding layer 26 is located in a chip structure region J1, and each bonding layer 26 includes a plurality of bonding patterns.

It should be noted that when the initial bonding layer 26′ is patterned, the plurality of bonding layers 26 are formed, and the bonding patterns included in each bonding layer 26 are also formed at the same time.

The bonding layer 26 is used to realize the connection between the first initial wafer and the second initial wafer in the subsequent assembly process.

In some embodiments, as shown in FIG. 22, step S3 includes steps S31 to S33.

In S31, as shown in FIG. 22, the second initial wafer B is arranged on a side of the first initial wafer A. The bonding layer 26 is arranged opposite to the buffer layer 11.

For example, the bonding layer 26 and the buffer layer 11 are bonded through a bonding process to realize the connection between the first initial wafer A and the second initial wafer B.

Compared with a metallic bonding layer to bond the first initial wafer A and the second initial wafer B, the adhesive bonding has better connection stability, which is more conducive to the connection stability of the chip structure 10.

In S32, a protective film is attached to a side of the first initial wafer A. The protective film covers the first initial wafer A and the remaining part of the second initial wafer B other than the initial first substrate 21′; and the protective film further covers the first surface of the initial first substrate 21′ and portions, proximate to the first surface, of a plurality of side surfaces of the initial first substrate 21′.

For example, the protective film includes, but is not limited to, an acid-proof film.

In S33, a thickness of the initial first substrate 21′ is reduced, so as to obtain the chip wafer structure 101.

For example, the initial first substrate 21′ is a glass substrate. When reducing the thickness of the initial first substrate 21′, the first initial wafer A with the protective film attached is placed in an etching solution (e.g., a potassium nitrate solution), the portions covered by the protective film will not be damaged by the etching solution, and an exposed portion of the initial first substrate 21′ is etched and thinned due to the etching solution. The first substrate is obtained by reducing the thickness of the initial first substrate 21′.

For example, as shown in FIG. 22, the thickness of the initial first substrate 21′ is h2. As shown in FIG. 23, a thickness of the first substrate 21 is h1, which is in a range of 60 μm to 200 μm; and h2 is greater than h1 (h2>h1).

Some embodiments of the present disclosure further provide a display substrate 100. As shown in FIGS. 23 and 24, the display substrate 100 includes a plurality of chip structures 10 as described in any of the above embodiments and a second substrate 20. A circuit structure is provided on a side of the second substrate 20 facing the chip structures 10. A second passivation layer 17 is provided on a side of the electrode layer 16 away from the color conversion substrate unit 2, and a pad layer 18 is provided on a side of the second passivation layer 17 away from the electrode layer 16. The pad layer 18 faces the second substrate 20, and is connected to the circuit structure of the second substrate 20. A minimum value of a distance between the second passivation layer 17 and the second substrate 20 is in a range of 15 μm to 25 μm.

For example, as shown in FIG. 23, the second substrate 20 includes, but is not limited to, a flexible printed circuit (FPC) or a printed circuit board (PCB).

In some embodiments, the pad layer 18 is soldered to the circuit structure using solder paste reflow, thereby realizing the connection between the chip structure 10 and the second substrate 20.

The circuit structure on the second substrate 20 is contact with the chip structure 10, causing the second passivation layer 17 to be damaged, so that the structures in the chip structure 10 that should be covered by the second passivation layer 17 are exposed, which will cause the chip structure 10 to be corroded by water and oxygen, which affects the working of the chip structure 10. Furthermore, when the circuit structure on the second substrate 20 damages the second passivation layer 17, the connection electrodes 162 may be exposed. When the connection electrodes 162 are in contact with the outside world, the connection electrodes 162 may be disconnected, which causes a short circuit problem in the light-emitting portion G that should form a series structure. As a result, the normal working of the chip structure 10 will be affected.

Compared with the case where the pad layer 18 is soldered to the circuit structure using soldering flux, the minimum value of the distance between the second passivation layer 17 and the second substrate 20 may be increased from a range within 10 μm to a range of 15 μm to 20 μm. This can effectively prevent the circuit structure on the second substrate 20 from being in contact with the chip structure 10, thereby avoiding the problem of damage to the chip structure 10 caused by the external structure (such as the second substrate 20) colliding with the chip structure 10.

For example, as shown in FIG. 24, the plurality of chip structures 10 in the display substrate 100 are arranged in the second direction Y and the third direction Z.

For example, as shown in FIG. 24, the display substrate 100 includes a plurality of pixels, and the plurality of pixels include sub-pixels P of at least three colors. The sub-pixels P of at least three colors include sub-pixels P1 of a first color, sub-pixels P2 of a second color, and sub-pixels P3 of a third color. The first color, second color and third color are three primary colors, such as red (R), green (G) and blue (B).

For example, as shown in FIG. 24, each sub-pixel P includes at least one light-emitting sub-portion g. The display substrate 100 using the chip structures 10 may satisfy the pixel pitch of 0.4 mm, thus achieving a good display effect.

For example, as shown in FIG. 2A, each light-emitting portion G includes two light-emitting sub-portions g, and each sub-pixel P includes one light-emitting portion G. A dimension of the chip structure in the second direction Y is, for example, 215 μm; and a dimension of the chip structure in the third direction Z is, for example, 225 μm. A dimension of the sub-pixel P in the second direction Y is, for example, 116 μm; and a dimension of the sub-pixel P in the third direction Z is, for example, 50 μm.

For another example, as shown in FIG. 2B, each light-emitting portion G includes three light-emitting sub-portions g, and each sub-pixel P includes one light-emitting portion G. The dimension of the chip structure in the second direction Y is, for example, 269 μm, and the dimension of the chip structure in the third direction Z is, for example, 260 μm. An area of the sub-pixel P1 of the first color and the sub-pixel P2 of the second color is, for example, 129 μm×60 μm+80 μm×60 μm. A dimension of the sub-pixel P3 of the third color in the second direction Y is, for example, 187 μm, and a dimension of the sub-pixel P3 of the third color in the third direction Z is, for example, 60 μm.

For yet another example, as shown in FIG. 2C, each light-emitting portion G includes four light-emitting sub-portions g, and each sub-pixel P includes one light-emitting portion G. The dimension of the chip structure in the second direction Y is, for example, 329 μm, and the dimension of the chip structure in the third direction Z is, for example, 238 μm. Dimensions of the sub-pixel P1 of the first color and the sub-pixel P2 of the second color in the second direction Y are each, for example, 129 μm, and dimensions of the sub-pixel P1 of the first color and the sub-pixel P2 of the second color in the third direction Z are each, for example, 118 μm. The dimension of the sub-pixel P3 of the third color in the second direction Y is, for example, 245 μm, and the dimension of the sub-pixel P3 of the third color in the third direction Z is, for example, 60 μm.

In the case where the above-mentioned chip structures 10 are used in the display substrate, a single chip structure 10 can realize multi-color display. For example, a single chip structure 10 can realize the display of three colors (R, G and

B). Compared with a design that a single chip structure only emits light of a single color, it can be understood that, under the same chip size, an area of a light-emitting region corresponding to a light-emitting portion G of each color in the chip structure 10 provided in some embodiments of the present disclosure is smaller, resulting in higher pixel accuracy of the display substrate 100.

Moreover, in the chip structure 10 provided in the embodiments of the present disclosure, at least two light-emitting sub-portions g are connected through connection electrode(s) 162 to form a light-emitting portion G of a series structure. Compared with the method of connecting multiple light-emitting devices in series to form a light-emitting device group, the size of the chip structure 10 provided in some embodiments of the present disclosure is smaller, which may satisfy the pixel pitch of 0.4 mm.

Some embodiments of the present disclosure provide a display apparatus. As shown in FIG. 25, the display apparatus includes the display substrate as described in the above embodiments.

Beneficial effects of the display apparatus are the same as those of the chip structure, which will not be repeated here.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A chip structure, comprising:
a chip wafer unit including a light-emitting layer and an electrode layer sequentially stacked in a first direction, wherein the light-emitting layer includes a plurality of light-emitting portions, each light-emitting portion includes at least two light-emitting sub-portions; the electrode layer includes a cathode, a plurality of connection electrodes, and a plurality of anodes in one-to-one correspondence with the plurality of light-emitting portions;
wherein at least two light-emitting sub-portions included in each light-emitting portion are sequentially connected through at least one connection electrode; among the at least two light-emitting sub-portions sequentially connected, a first one light-emitting sub-portion is a first selected light-emitting sub-portion, and a last one light-emitting sub-portion is a second selected light-emitting sub-portion; the first selected light-emitting sub-portion is connected to the cathode, and the second selected light-emitting sub-portion is connected to an anode corresponding to the light-emitting portion; and
a color conversion substrate unit disposed on a light-exit side of the chip wafer unit;
wherein the first direction is a direction perpendicular to a lower surface of the color conversion substrate unit and pointing from the color conversion substrate unit to the chip wafer unit.

2. The chip structure according to claim 1, wherein a quantity of light-emitting sub-portions included in each light-emitting portion of the plurality of light-emitting portions is the same.

3. The chip structure according to claim 2, wherein light-emitting sub-portions in the plurality of light-emitting portions include first light-emitting sub-portions, second light-emitting sub-portions, and third light-emitting sub-portions; and
the plurality of light-emitting portions include:
a first light-emitting portion including at least two first light-emitting sub-portions;
a second light-emitting portion including at least two second light-emitting sub-portions;
and
a third light-emitting portion including at least two third light-emitting sub-portions.

4. The chip structure according to claim 3, wherein a surface of the color conversion substrate unit facing the chip wafer unit is a first surface;
the chip wafer unit further includes N-type gallium nitride portions, the N-type gallium nitride portions include first N-type gallium nitride patterns and a plurality of second N-type gallium nitride patterns, and the first N-type gallium nitride patterns are connected to the cathode;
each light-emitting sub-portion includes an N-type gallium nitride portion and a light-emitting functional portion that are stacked in the first direction; a boundary of an orthographic projection of the N-type gallium nitride portion on the first surface surrounds a boundary of an orthographic projection of the light-emitting functional portion on the first surface;
an N-type gallium nitride portion included in the first selected light-emitting sub-portion is a first N-type gallium nitride pattern, and an N-type gallium nitride portion included in a light-emitting sub-portion other than the first selected light-emitting sub-portion is a second N-type gallium nitride pattern.

5. The chip structure according to claim 4, wherein the light-emitting functional portion includes a quantum well portion, a P-type gallium nitride portion and a conductive portion that are stacked in the first direction; each anode of the plurality of anodes is arranged corresponding to a single second selected light-emitting sub-portion, and is connected to a conductive portion of the single second selected light-emitting sub-portion;
the chip wafer unit further includes:
a transfer layer including a cathode transfer electrode disposed on a side of the first N-type gallium nitride pattern away from the first surface; an orthographic projection of the cathode transfer electrode on the first surface does not overlap with the orthographic projection of the light-emitting functional portion on the first surface; and
a first passivation layer disposed on a side of the light-emitting layer away from the first surface and covering the light-emitting layer and the transfer layer; wherein the electrode layer is disposed on a side of the first passivation layer away from the light-emitting layer; and the first passivation layer includes:
a first via hole reaching the cathode transfer electrode;
a plurality of second via holes, wherein each second via hole is arranged corresponding to a single light-emitting sub-portion, and the plurality of second via holes reach conductive portions of light-emitting sub-portions, respectively; the plurality of second via holes include a plurality of transfer via holes and a plurality of connection via holes, and each transfer via hole of the plurality of transfer via holes is arranged corresponding to one second selected light-emitting sub-portion; and
a plurality of third via holes, wherein each third via hole is arranged corresponding to a single light-emitting sub-portion other than the first selected light-emitting sub-portion, and the plurality of third via holes reach N-type gallium nitride portions of the light-emitting sub-portions, respectively;
wherein the cathode is connected to the cathode transfer electrode through the first via hole; each anode is connected to the conductive portion of the single second selected light-emitting sub-portion through a transfer via hole; a first end of any one connection electrode of the plurality of connection electrodes is connected to a conductive portion of one light-emitting sub-portion of the at least two light-emitting sub-portions through a connection via hole, and a second end of the connection electrode is connected to an N-type gallium nitride portion of another light-emitting sub-portion through a third via hole.

6. The chip structure according to claim 5, wherein the chip wafer unit further includes a second passivation layer and a pad layer that are stacked in the first direction,
the second passivation layer covering the electrode layer and including: a fourth via hole arranged corresponding to the first via hole and a plurality of fifth via holes arranged corresponding to the plurality of transfer via holes, wherein the fourth via hole reaches the cathode, and the plurality of fifth via holes respectively reach the anodes; and
the pad layer including a first pad and a plurality of second pads in one-to-one correspondence with the plurality of anodes, wherein the first pad is connected to the cathode through the fourth via hole, and each second pad is connected to an anode through a fifth via hole.

7. The chip structure according to claim 4,
wherein the chip wafer unit further includes a buffer layer and a U-type gallium nitride layer that are stacked in the first direction,
the U-type gallium nitride layer being disposed between the buffer layer and the light-emitting layer;
wherein the first passivation layer further covers the U-type gallium nitride layer and the buffer layer.

8. The chip structure according to claim 7, wherein a thickness of the buffer layer in the first direction is in a range of 4.5 μm to 5.5 μm.

9. The chip structure according to claim 5, wherein a boundary of an orthographic projection of the quantum well portion of the light-emitting sub-portion on the first surface has a size in a second direction that is in a range of 18μm to 21 μm and a size in a third direction that is in a range of 18 μm to 21 μm;
wherein the second direction intersects the third direction, the second direction is perpendicular to the first direction, and the third direction is perpendicular to the first direction.

10. The chip structure according to claim 5, wherein in any one light-emitting sub-portion, a distance between a boundary of an N-type gallium nitride portion and a boundary of a P-type gallium nitride portion is r1;
in the second selected light-emitting sub-portion, a distance between a boundary of a second N-type gallium nitride pattern and a boundary of a corresponding third via hole is r2, where r1>r2.

11. The chip structure according to claim 10, wherein in the light-emitting sub-portion, the distance between the boundary of the N-type gallium nitride portion and the boundary of the P-type gallium nitride portion is in a range of 9.5 μm to 10.5 μm;
a distance between a boundary of any second N-type gallium nitride pattern and any third via hole is greater than or equal to 5 μm;
a distance between the first N-type gallium nitride pattern and any one of the plurality of second N-type gallium nitride patterns is greater than or equal to 6 μm;
a distance between any two of the plurality of second N-type gallium nitride patterns is greater than or equal to 6 μm.

12. The chip structure according to claim 5, wherein a distance between the cathode transfer electrode and the quantum well portion is greater than or equal to 8 μm.

13. The chip structure according to claim 3, wherein the color conversion substrate unit includes:
a first substrate;
a color filter layer disposed on a side of the first substrate facing the chip wafer unit and including a black matrix and a plurality of filter portions defined by the black matrix, the plurality of filter portions being in one-to-one correspondence with the plurality of light-emitting portions, wherein the plurality of filter portions include: a first color filter portion arranged corresponding to the first light-emitting portion, a second color filter portion arranged corresponding to the second light-emitting portion, and a third color filter portion arranged corresponding to the third light-emitting portion;
a definition dam layer disposed on a side of the color filter layer away from the first substrate and including a plurality of opening regions in one-to-one correspondence with the plurality of filter portions, wherein the plurality of opening regions include: a first opening region arranged corresponding to the first color filter portion, a second opening region arranged corresponding to the second color filter portion, and a third opening region arranged corresponding to the third color filter portion;
a color conversion layer disposed in the plurality of opening regions and including color conversion portions and a filling portion; wherein the filling portion is disposed in the third opening region;
an encapsulation layer covering the definition dam layer and the color conversion layer; and
a bonding layer disposed on a side of the encapsulation layer away from the first substrate.

14. The chip structure according to claim 13, wherein the color conversion portions include a first color conversion portion disposed in the first opening region and a second color conversion portion disposed in the second opening region;
the first color conversion portion includes a first quantum dot conversion portion or a first fluorescent color conversion portion;
the second color conversion portion includes a second quantum dot conversion portion or a second fluorescent color conversion portion; and
the filling portion includes a scattering particle portion or a transparent glue.

15. The chip structure according to claim 13 44, wherein a light-emitting region of the chip structure corresponding to the first light-emitting portion is a light-emitting region of a first color, a light-emitting region of the chip structure corresponding to the second light-emitting portion is a light-emitting region of a second color, and a light-emitting region of the chip structure corresponding to the third light-emitting portion is a light-emitting region of a third color;
wherein the first color is red, the second color is green, and the third color is blue.

16. The chip structure according to claim 15, wherein a light-emitting area of the first light-emitting portion is equal to a light-emitting area of the second light-emitting portion, and the light-emitting area of the first light-emitting portion is greater than or equal to a light-emitting area of the third light-emitting portion.

17. A display substrate, comprising:
a plurality of chip structures according to claim 1, wherein a second passivation layer is provided on a side of the electrode layer away from the color conversion substrate unit, and a pad layer is provided on a side of the second passivation layer away from the electrode layer; and
a second substrate, wherein a circuit structure is provided on a side of the second substrate facing the chip structures; the pad layer faces the second substrate and is connected to the circuit structure;
a minimum value of a distance between the second passivation layer and the second substrate is in a range of 15 μm to 25 μm.

18. A display apparatus, comprising the display substrate according to claim 17.

19. A method of manufacturing a chip structure, comprising:
forming a first initial wafer, wherein the first initial wafer includes a plurality of initial chip wafer units; each initial chip wafer unit includes a plurality of chip structure regions; each initial chip wafer unit further includes: an initial substrate, and an initial light-emitting layer and an initial electrode layer that are sequentially stacked on a first surface of the initial substrate in a first direction; the initial light-emitting layer includes light-emitting portions; the initial electrode layer includes cathodes, connection electrodes, and anodes in one-to-one correspondence with the light-emitting portions;
forming a second initial wafer, wherein the second initial wafer includes a plurality of initial color conversion substrate units;
arranging the second initial wafer on a light-exit side of the first initial wafer for assembly to obtain a chip wafer structure, wherein the chip wafer structure includes a plurality of chip structures;
cutting the chip wafer structure along border lines of the chip structure regions to obtain the plurality of chip structures, wherein each chip structure includes a plurality of light-emitting portions, and each light-emitting portion includes at least two light-emitting sub-portions; each chip structure further includes a cathode, a plurality of connection electrodes, and a plurality of anodes in one-to-one correspondence with the plurality of light-emitting portions; the at least two light-emitting sub-portions included in each light-emitting portion are sequentially connected through at least one connection electrode; among the at least two light-emitting sub-portions sequentially connected, a first one light-emitting sub-portion is a first selected light-emitting sub-portion, and a last one light-emitting sub-portion is a second selected light-emitting sub-portion; the first selected light-emitting sub-portion is connected to the cathode, and the second selected light-emitting sub-portion is connected to an anode corresponding to the light-emitting portion.

20. The method according to claim 19, wherein
the initial light-emitting layer includes an initial N-type gallium nitride layer and an initial light-emitting functional layer sequentially stacked in the first direction;
the initial N-type gallium nitride layer includes a plurality of N-type gallium nitride portions, and the plurality of N-type gallium nitride portions include a plurality of first N-type gallium nitride patterns and a plurality of second N-type gallium nitride patterns; each chip structure region includes first N-type gallium nitride patterns and second N-type gallium nitride patterns;
the initial light-emitting functional layer includes a quantum well layer, a P-type gallium nitride layer, and a conductive layer that are sequentially stacked in the first direction, wherein the quantum well layer includes a plurality of quantum well portions, the P-type gallium nitride layer includes a plurality of P-type gallium nitride portions, and the conductive layer includes a plurality of conductive portions; each light-emitting functional portion includes a quantum well portion, a P-type gallium nitride portion and a conductive portion that are stacked; an N-type gallium nitride portion included in the first selected light-emitting sub-portion is a first N-type gallium nitride pattern, and an N-type gallium nitride portion included in the second selected light-emitting sub-portion is a second N-type gallium nitride pattern;
before a step of cutting the chip wafer structure, the method further comprises:
forming an initial transfer layer, wherein the initial transfer layer includes a plurality of cathode transfer electrodes, each cathode transfer electrode is disposed on a side of a first N-type gallium nitride pattern away from the initial substrate;
forming an initial first passivation layer, wherein the initial first passivation layer is disposed on a side of the initial light-emitting layer away from the initial substrate; the initial first passivation layer includes a plurality of first via holes, a plurality of second via holes, and a plurality of third via holes; each first via hole is arranged corresponding to a first selected light emitting sub-portion, and the plurality of first via holes respectively reach the cathode transfer electrodes; each second via hole is arranged corresponding to a light-emitting sub-portion, and the plurality of second via holes respectively reach the conductive portions; each third via hole is arranged corresponding to a light-emitting sub-portion other than the first selected light-emitting sub-portion, and the plurality of third via holes respectively reach N-type gallium nitride portions of light-emitting sub-portions;
forming an initial second passivation layer, wherein the initial second passivation layer is disposed on a side of the initial electrode layer away from the initial substrate; the initial second passivation layer includes a plurality of fourth via holes in one-to-one correspondence with the plurality of first via holes, and a plurality of fifth via holes in one-to-one correspondence with a plurality of transfer via holes included in the plurality of second via holes; and
forming a pad layer, wherein the pad layer includes a plurality of first pads and a plurality of second pads, each first pad is connected to a cathode through a fourth via hole, and each second pad is connected to one of the plurality of anodes through a fifth via hole.
